(19) United States
(12) Patent Application Publication
(10) Pub. No.: US 2026/0304691 A1
(43) Pub. Date: Oct. 1, 2026

(54) APPARATUS, SYSTEMS, AND METHODS OF USE FOR AN OUTDOOR MOUNTED TEMPERATURE REGULATING ENCLOSURE

(71) Applicant: Iceotope Group Limited, South Yorkshire (GB)

(72) Inventors: Neil Edmunds, Ylöjärvi (FI); Alexander Cushen, South Yorkshire (GB)

(73) Assignee: Iceotope Group Limited, South Yorkshire (GB)

(21) Appl. No.: 19/636,704

(22) Filed: Apr. 1, 2026

Related U.S. Application Data
(60) Provisional application No. 63/906,199, filed on Oct. 27, 2025.
(60) Provisional application No. 63/906,196, filed on Oct. 27, 2025.
(60) Provisional application No. 63/781,909, filed on Apr. 1, 2025.

(51) Int. Cl. H05K 7/20; H05K 5/02

(52) U.S. Cl. CPC H05K 7/20272; H05K 5/0204; H05K 7/20172; H05K 7/20236; H05K 7/20263; H05K 7/20163; H05K 7/20281

(57) ABSTRACT

A cooling enclosure apparatus comprising an enclosure configured to be mounted to an outdoor structure. The cooling enclosure apparatus comprises a chassis enclosed within the enclosure, the chassis including one or more heat fins. The cooling enclosure apparatus comprises an IT board disposed within the chassis, the IT board having at least one electronic component disposed upon a surface thereof, wherein the chassis contains a sufficient amount of dielectric fluid to at least partially submerge the IT board. The cooling enclosure apparatus comprises one or more radiators disposed adjacent to the exterior surface of the chassis, the one or more radiators being fluidly connected to the chassis interior space. The cooling enclosure apparatus comprises one or more pumps configured to move dielectric fluid from the chassis interior space, through the one or more radiators, and back into the chassis interior space.

### CROSS-REFERENCE TO RELATED APPLICATIONS

This application claims priority to U.S. Application No. 63/781,909, titled APPARATUS, SYSTEMS, AND METHODS OF USE FOR AN OUTDOOR MOUNTED TEMPERATURE REGULATING ENCLOSURE, filed Apr. 1, 2025, U.S. Application No. 63/906,196, titled APPARATUS, SYSTEMS, AND METHODS OF USE FOR AN OUTDOOR MOUNTED TEMPERATURE REGULATING ENCLOSURE, filed Oct.27, 2025, and U.S. Application No. 63/906,199, titled APPARATUS, SYSTEMS, AND METHODS OF USE FOR AN OUTDOOR MOUNTED TEMPERATURE REGULATING ENCLOSURE, filed Oct. 27, 2025, which are hereby incorporated by reference in their entirety.

### FIELD OF THE PRESENT DISCLOSURE

The present disclosure relates to outdoor-mounted electronic equipment cooling systems. Specifically, the present disclosure relates to a pole-mounted temperature regulating enclosure with active and passive cooling capabilities for information technology equipment using dielectric fluid circulation and external radiators.

### INTRODUCTION

Information technology equipment generates substantial heat during operation, particularly in high-performance computing applications. As processing power and component density continue to increase, thermal management has become a significant challenge for maintaining optimal performance and preventing component failure. Traditional air cooling methods often prove inadequate for modern electronic systems, leading to the development of liquid cooling solutions that can more effectively transfer heat away from critical components.

Outdoor deployment of electronic equipment presents additional thermal management challenges beyond those encountered in controlled indoor environments. Ambient temperature variations, weather conditions, and limited access to traditional cooling infrastructure create complex requirements for thermal regulation systems. Equipment must be capable of operating across wide temperature ranges while maintaining performance and reliability standards.

Dielectric fluid cooling systems have emerged as a solution for high-heat-density applications, offering superior thermal transfer properties compared to air cooling. These systems typically involve immersing electronic components in non-conductive fluids that can absorb and transport heat more efficiently than air. However, implementing such systems in outdoor environments creates difficulties in managing fluid circulation, heat rejection, and temperature control across varying environmental conditions.

Pole-mounted installations are used for telecommunications and edge computing applications, where equipment must be positioned for optimal signal coverage or network connectivity. These installations face particular challenges in thermal management due to space constraints, limited power availability, and exposure to environmental extremes. Effective cooling solutions for pole-mounted equipment must balance thermal performance with size, weight, and power consumption considerations.

Current cooling approaches for outdoor electronic equipment often rely on either passive heat dissipation or simple fan-based active cooling. While these methods may be adequate for lower power applications, they can become insufficient as equipment power densities increase. More sophisticated thermal management systems that can adapt to varying environmental conditions and equipment loads would provide improved performance and reliability for outdoor electronic installations.

Accordingly, there remains a need for improved thermal management solutions addressing the challenges of outdoor electronic equipment deployment while providing effective temperature regulation across varying environmental conditions.

### SUMMARY

This Summary is provided to introduce a selection of concepts in a simplified form that are further described below in the Detailed Description. This Summary is not intended to identify key features or essential features, nor is it intended to limit the scope of the claims included herewith.

According to an aspect of the present disclosure, a cooling enclosure apparatus may be provided. The cooling enclosure apparatus may comprise an enclosure configured to be mounted to an outdoor structure. The cooling enclosure apparatus may further comprise a chassis enclosed within an enclosure, the chassis including one or more heat fins. The cooling enclosure apparatus may comprise an IT board disposed within the chassis, the IT board having at least one electronic component disposed upon a surface thereof, wherein the chassis contains a sufficient amount of dielectric fluid to at least partially submerge the IT board. The cooling enclosure apparatus may comprise one or more radiators disposed adjacent to the exterior surface of the chassis, the one or more radiators being fluidly connected to the chassis interior space. The cooling enclosure apparatus may comprise one or more pumps configured to move dielectric fluid from the chassis interior space, through the one or more radiators, and back into the chassis interior space.

According to other aspects of the present disclosure, the cooling enclosure apparatus may include one or more of the following features. The one or more radiators and the chassis may define a coolant channel, wherein dielectric fluid circulates through the coolant channel to transfer heat to the one or more radiators. The cooling enclosure apparatus may further comprise a heater printed circuit board disposed within the chassis interior space and submerged in the dielectric fluid, wherein the heater printed circuit board comprises a plurality of resistors configured to generate heat to warm the dielectric fluid. The cooling enclosure apparatus may further comprise a controller communicatively coupled to the heater printed circuit board, wherein the controller is configured to selectively activate portions of the plurality of resistors based on a temperature of the dielectric fluid. The plurality of resistors may be configured to be activated in stages at different temperature thresholds to distribute power consumption over time. The cooling enclosure apparatus may further comprise a coolant displacement block disposed within the chassis interior space, wherein the coolant displacement block is hollow and configured to displace dielectric fluid within the chassis to reduce an overall weight of the cooling enclosure apparatus. The coolant displacement block may be positioned within a spare power supply port of the chassis. The cooling enclosure apparatus may further comprise one or more fans may be incorporated into a removable fan module. The cooling enclosure apparatus may further comprise a heatsink thermally coupled to an electronic component disposed on the IT board, wherein the heatsink includes one or more slotted inlets configured to distribute dielectric coolant across a plurality of cooling fins extending from a base of the heatsink. The cooling enclosure apparatus may further comprise piping fluidly connecting a radiator outlet to the heatsink, wherein the piping is configured to deliver cooled dielectric fluid from the one or more radiators directly to the heatsink prior to the dielectric fluid entering the chassis interior space. The cooling enclosure apparatus may further comprise a coolant distribution manifold fluidly connected to the heatsink via piping, wherein the coolant distribution manifold is configured to receive warmed dielectric coolant from the heatsink and distribute the warmed dielectric coolant to a bottom portion of the chassis interior space.

According to another aspect of the present disclosure, a thermal management system for outdoor electronic equipment may be provided. The thermal management system may comprise a weatherproof enclosure configured for pole mounting. The thermal management system may comprise a thermally conductive chassis positioned within the weatherproof enclosure, the chassis defining an interior space containing dielectric fluid. The thermal management system may comprise an IT board submerged in the dielectric fluid within the chassis interior space, the IT board supporting a plurality of electronic components. The thermal management system may comprise a heatsink thermally coupled to at least one of the plurality of electronic components. The thermal management system may comprise a radiator assembly fluidly connected to the chassis interior space, the radiator assembly and the thermally conductive chassis defining a coolant channel. The thermal management system may comprise a pump configured to circulate the dielectric fluid between the chassis interior space and the radiator assembly. The thermal management system may comprise a fan assembly positioned adjacent to the radiator assembly to direct airflow therethrough.

According to other aspects of the present disclosure, the thermal management system may include one or more of the following features. The heatsink may include one or more slotted inlets configured to distribute the dielectric fluid across a plurality of cooling fins extending from a base of the heatsink, and one or more slotted exit holes configured to facilitate controlled overflow of the dielectric fluid from the heatsink into the chassis interior space. The thermal management system may further comprise piping fluidly connecting a radiator outlet to the heatsink, wherein the piping may be configured to deliver cooled dielectric fluid from the radiator assembly directly to the heatsink prior to the dielectric fluid entering the chassis interior space. The thermal management system may further comprise a coolant displacement block disposed within the chassis interior space, wherein the coolant displacement block is hollow and positioned within a spare power supply port of the chassis to displace dielectric fluid and reduce an overall weight of the thermal management system. The thermal management system may further comprise a heater printed circuit board disposed within the chassis interior space and submerged in the dielectric fluid, wherein the heater printed circuit board comprises a bank of resistors configured to generate heat to warm the dielectric fluid, and a controller communicatively coupled to the heater printed circuit board and configured to selectively activate portions of the bank of resistors based on a temperature of the dielectric fluid. The fan assembly may comprise a removable fan module incorporating a plurality of individual fan units mechanically coupled within a common mounting framework, wherein the removable fan module is configured to be removed from the weatherproof enclosure as a single unit for servicing.

According to another aspect of the present disclosure, a method of thermally regulating electronic equipment in an outdoor environment may be provided. The method may comprise mounting an enclosure to an outdoor structure, the enclosure containing a chassis with an IT board disposed therein. The method may comprise submerging the IT board in dielectric fluid contained within the chassis. The method may comprise circulating the dielectric fluid from the chassis through one or more radiators using one or more pumps, wherein the one or more radiators and the chassis define a coolant channel therebetween. The method may comprise directing airflow through the one or more radiators using one or more fans to transfer heat from the dielectric fluid to an ambient environment.

According to other aspects of the present disclosure, the method may include one or more of the following features. The method may further comprise activating a heater printed circuit board disposed within the chassis interior space and submerged in the dielectric fluid to warm the dielectric fluid when an ambient temperature or a temperature of the dielectric fluid drops below a specific temperature threshold, wherein the heater printed circuit board comprises a plurality of resistors configured to generate heat. The method may further comprise routing cooled dielectric fluid from the one or more radiators directly to a heatsink thermally coupled to an electronic component generating a highest thermal output among electronic components on the IT board prior to the dielectric fluid entering the chassis interior space, wherein the electronic component may comprise a processor, a graphics processing unit, or similar high-power component.

### BRIEF DESCRIPTION OF FIGURES

Non-limiting and non-exhaustive examples are described with reference to the following figures.

FIG. 1 is a block diagram of an embodiment of a two-phase cooling system.

FIG. 2 is an embodiment of a cooling enclosure apparatus.

FIG. 3A is an illustration of an embodiment of a cooling enclosure apparatus.

FIG. 3B is an illustration of an embodiment of a cooling enclosure apparatus.

FIG. 3C is an illustration of an embodiment of a cooling enclosure apparatus.

FIG. 3D is an illustration of an embodiment of a cooling enclosure apparatus.

FIG. 3E is an illustration of an embodiment of a cooling enclosure apparatus.

FIG. 4 is an illustration of an embodiment of one or more temperature control phases.

FIG. 5 is an illustration of an embodiment of a cooling enclosure apparatus.

FIG. 6A is an illustration of an embodiment of a cooling enclosure apparatus.

FIG. 6B is an illustration of an embodiment of a cooling enclosure apparatus.

FIG. 7A is an illustration of an embodiment of a cooling enclosure apparatus.

FIG. 7B is an illustration of an embodiment of a cooling enclosure apparatus.

FIG. 7C is an illustration of an embodiment of a cooling enclosure apparatus.

FIG. 7D is an illustration of an embodiment of a cooling enclosure apparatus.

FIG. 7E is an illustration of an embodiment of a cooling enclosure apparatus.

FIG. 8A is an illustration of an embodiment of a heatsink.

FIG. 8B is an illustration of an embodiment of a heatsink.

FIG. 9A is an illustration of an embodiment of a heatsink.

FIG. 9B is an illustration of an embodiment of a heatsink.

FIG. 10 is an illustration of an embodiment of a heatsink.

FIG. 11A is an illustration of an embodiment of a heatsink.

FIG. 11B is an illustration of an embodiment of a heatsink.

FIG. 12 is an illustration of an embodiment of a heatsink.

FIG. 13A is an illustration of an embodiment of a cooling enclosure apparatus.

FIG. 13B is an illustration of an embodiment of a cooling enclosure apparatus.

FIG. 13C is an illustration of an embodiment of a cooling enclosure apparatus.

FIG. 14 is an illustration of an embodiment of a fan module.

### DETAILED DESCRIPTION

In the following detailed description, reference will be made to the accompanying drawing(s), in which identical functional elements are designated with like numerals. The aforementioned accompanying drawings show by way of illustration, and not by way of limitation, specific aspects, and implementations consistent with principles of this disclosure. These implementations are described in sufficient detail to enable those skilled in the art to practice the disclosure and it is to be understood that other implementations may be utilized and that structural changes and/or substitutions of various elements may be made without departing from the scope and spirit of this disclosure. The following detailed description is, therefore, not to be construed in a limited sense.

It is noted that description herein is not intended as an extensive overview, and as such, concepts may be simplified in the interests of clarity and brevity.

All documents mentioned in this application are hereby incorporated by reference in their entirety. Any process described in this application may be performed in any order and may omit any of the steps in the process. Processes may also be combined with other processes or steps of other processes.

Aspects of the present disclosure may relate to a cooling enclosure apparatus configured for outdoor deployment. For example, such a cooling enclosure apparatus may be configured for pole mounting, however, one of ordinary skill in the art will recognize that the enclosure may be deployed outdoors more broadly. The cooling enclosure apparatus may provide thermal management for electronic equipment using immersion cooling with integrated radiators and pumps.

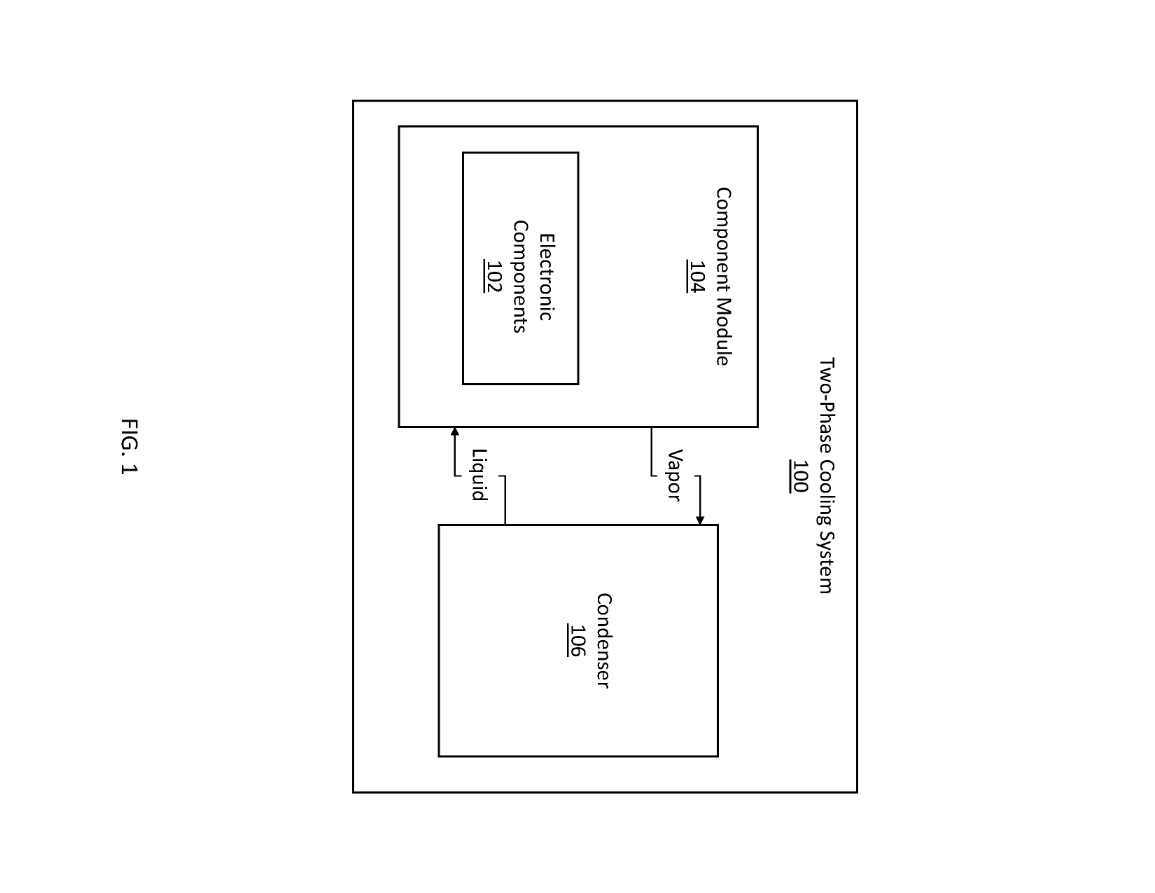

Referring to FIG. 1 , in one or more embodiments, such a cooling enclosure apparatus may include a two-phase cooling system 100. Such a two-phase cooling system 100 may employ a two-phase coolant for cooling one or more heat generating electronic components 102.

In an embodiment, the two-phase cooling system 100 may comprise the one or more heat generating electronic components (the “electronic components”) 102 housed within a component module 104. The electronic components 102 may include components such as Central Processing Units (CPUs), Graphics Processing Units (GPUs), memory modules (e.g., DIMMs), Power Supply Units (PSUs), and the like. Said electronic components 102 may be disposed upon a Printed Circuit Board (PCB) housed within the component module 104.

In one or more embodiments, the component module 104 may be partially or fully filled with a two-phase dielectric coolant. Thus, the electronic components 102 may correspondingly be partially or fully submerged in the two-phase dielectric coolant, thereby enabling heat transfer from the components 102 to the coolant. In an embodiment, the two-phase cooling system 100 may include a first set of one or more pumps disposed within the component module 104 for circulating the two-phase dielectric coolant.

To illustrate, the two-phase dielectric coolant may partially or fully submerge the one or more heat generating electronic components 102 in a liquid state. As the electronic components 102 generate heat through their operation, latent heat energy may be transferred to the two-phase dielectric coolant causing a portion of the coolant to undergo a first phase change from the liquid state to a vapor state.

In one or more embodiments, the two-phase cooling system 100 may feature a cold plate disposed within the component module 104. Thus, as the two-phase dielectric coolant undergoes the first phase change, transforming the coolant from a liquid to a vapor, the vapor may rise towards and interface with the cold plate such that it undergoes a second phase change. Specifically, the cold plate may cool the vapor such that the vapor condenses and transforms back into a liquid for recirculation within the component module 104.

Such a cold plate may incorporate independent inlet and outlet connections to an external facility cooling loop for receiving and rejecting an external coolant (e.g., water). To illustrate, the external coolant may enter the cold plate via the independent inlet, wherein said external coolant receives heat from the two-phase dielectric coolant in its vapor state facilitating the second phase change. Subsequently, the warmed external coolant may exit the cold plate via the independent outlet, wherein it is cooled by the external facility cooling loop for recirculation to the cold plate.

Such a configuration may exploit the passive movement of the vapor from the one or more electronic components 102 to the cold plate, driven by the vapor’s inherent buoyancy or pressure differentials within the component module 104. For example, the cold plate may be located at an upper portion of the component module 104, positioned above the one or more electronic components 102, allowing the vapor to naturally rise towards the cold plate and passively fall towards a bottom portion of the component module 104 as it cools to interface with the electronic components 102 for cooling.

In one or more embodiments, the two-phase cooling system 100 may include an external condenser 106 that facilitates the second phase change of the two-phase dielectric coolant. In an embodiment, the condenser 106 may receive heat from the two-phase dielectric coolant in its vapor state facilitating the second phase change. As a nonlimiting example, the condenser 106 may include, but is not limited to, shell-and-tube condensers, plate-and-fin air-cooled coils, evaporative condensers, and the like. Further, external placement of the condenser 106 may facilitate improved heat rejection of the two-phase dielectric coolant by increasing exposure to ambient air and/or enabling integration with additional cooling components, such as fans, heat exchangers, or liquid cooling loops. Once the vapor condenses within the condenser 106, the resulting liquid may return to the component module 104.

To illustrate, upon receiving heat from the one or more electronic components 102, and undergoing the first phase change, the two-phase dielectric coolant in its vapor state may be directed outside of the component module 104 via a first piping arrangement towards the condenser 106. For instance, the first piping arrangement may interface with both the component module 104 and condenser 106, facilitating movement of the dielectric coolant in its vapor state from the component module 104 to the condenser 106. As a nonlimiting example, the first piping arrangement may comprise an outlet at the top portion of the component module 104 facilitating movement of the vapor to an inlet incorporated in the condenser 106.

In one embodiment, the condenser 106 may be positioned above the component module 104 enabling passive movement of the two-phase dielectric coolant in its vapor state from the component module 104 to the condenser 106 via the first piping arrangement. To illustrate, upon entering the condenser 106 the two-phase dielectric coolant in its vapor state may be cooled, transforming back into a liquid state, wherein the liquid two-phase dielectric coolant passively flows back into the component module 104 via a second piping arrangement.

The second piping arrangement may interface with both the component module 104 and condenser 106, facilitating movement of the dielectric coolant in its liquid state from the condenser 106 to the component module 104. As a nonlimiting example, the second piping arrangement may comprise an outlet incorporated within the condenser 106 facilitating movement of the two-phase dielectric coolant in its liquid state to an inlet incorporated in the component module 104.

In another embodiment, the two-phase cooling system 100 may employ the first set of one or more pumps and/or a second set of one or more pumps to drive the two-phase dielectric coolant to and from the component module 104. For instance, the first and/or second set of one or more pumps may drive the two-phase dielectric coolant in its vapor state from the component module 104 to the condenser 106 via the first piping arrangement.

The first and/or second set of one or more pumps may drive the two-phase dielectric coolant in its liquid state from the condenser 106 to the component module 104 for cooling the electronic components 102 therein. As a nonlimiting example, the condenser 106 may be located adjacent to or below the component module 104.

In one or more embodiments, the two-phase dielectric coolant in its liquid state may be routed from the condenser 106 to a filtration unit via the second piping arrangement. The filtration unit may be configured to remove contaminants or particulates that may be introduced during the evaporation or condensation phases of the coolant cycle. The filtration unit may be fluidly coupled between the condenser 106 and the component module 104, thereby ensuring that only purified liquid dielectric coolant is reintroduced into the component module 104 to interface with the one or more electronic components 102. As a nonlimiting example, the filtration unit may be near the site housing the condenser 106, proximate to the condenser 106, or coupled to an external compartment housing the condenser 106. In another nonlimiting example, the filtration unit may be positioned near the electronic components 102 to facilitate delivery of cooled, filtered dielectric coolant directly to said components 102.

In an embodiment, the second set of one or more pumps may be disposed downstream of the filtration unit and may be operable to drive the filtered dielectric coolant through one or more pipes back to the component module 104. In one or more embodiments, the second set of one or more pumps may operate continuously or intermittently based on conditions within the two-phase cooling system 100 to maintain a closed-loop circulation of the coolant.

In one or more embodiments, the cooling enclosure apparatus described herein may incorporate such a two-phase cooling system 100.

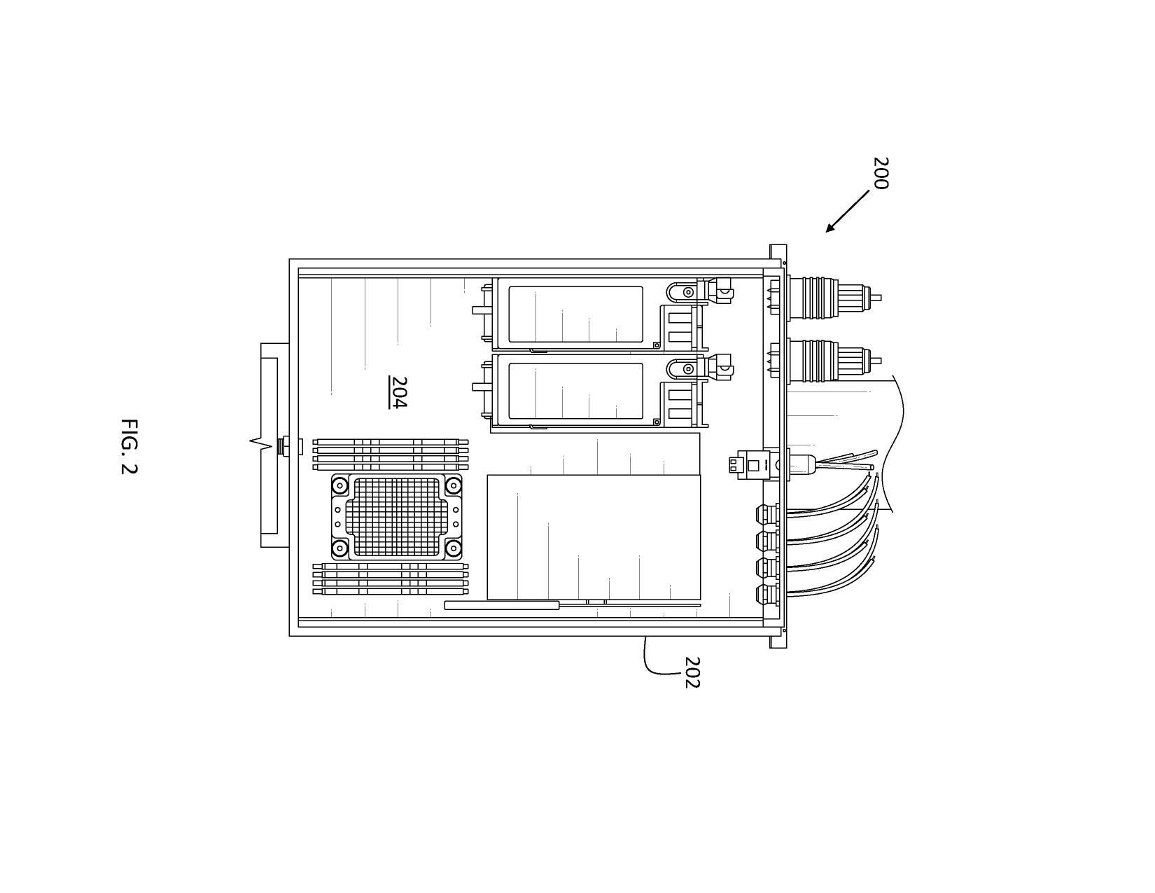

Referring to FIG. 2, aspects of the present disclosure may relate to an enclosure 200 capable of regulating temperatures in outdoor weather conditions. Such an enclosure 200 may incorporate the two-phase cooling system 100 as previously described. In an embodiment, the enclosure 200 may enclose a chassis 202. The chassis 202 may comprise an interior space housing an information technology (“IT”) board such as the IT Board 204.

In one or more embodiments, the IT Board 204 may be configured to accommodate various electronic components such as CPUs, memory modules, GPUs, PSUs, or any other suitable electronic component. The IT Board 204 may include one or more Peripheral Component Interconnect Express (“PCIe”) ports, Non-Volatile Memory Express (“NVMe”) ports, or other suitable connection interface for interfacing with various external peripherals.

In an embodiment, the interior space of the chassis 202 may contain dielectric fluid that at least partially submerges the IT Board 204 to facilitate the transfer of thermal energy to or from the electronic components thereon. The dielectric fluid may interact with a variety of systems to achieve and maintain an optimal temperature range of said electronic components.

The enclosure 200 may comprise a weatherproof housing designed to protect the electronic components from environmental exposure while facilitating thermal management operations. Walls comprising the enclosure 200 may be constructed from materials providing structural integrity and thermal conductivity properties suitable for outdoor installations. In an embodiment, the chassis 202 may be constructed from a material having high heat conductivity such as aluminum or other suitably conductive metal or material to facilitate heat transfer from internal electronic components mounted on the IT Board 204, or otherwise disposed within the chassis 202, to external cooling systems. In one example, the chassis 202 may include one or more fins 302 (described in more detail below) extending outwardly from its exterior surfaces to increase surface area available for heat dissipation. Said fins 302 may be integrally formed with the chassis 202 or may be attached as separate components.

In some cases, the enclosure 200 may include mounting provisions for attachment to pole structures or other support systems commonly used in telecommunications and edge computing deployments.

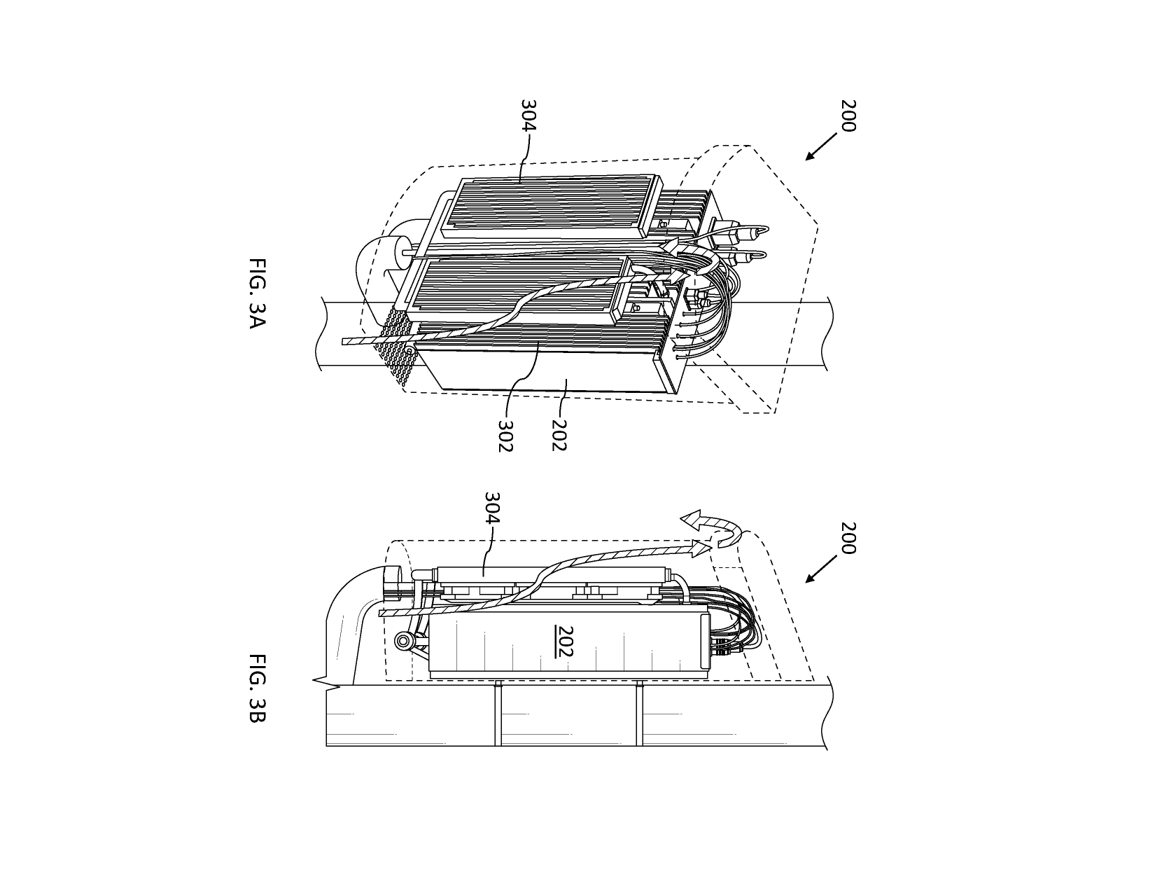

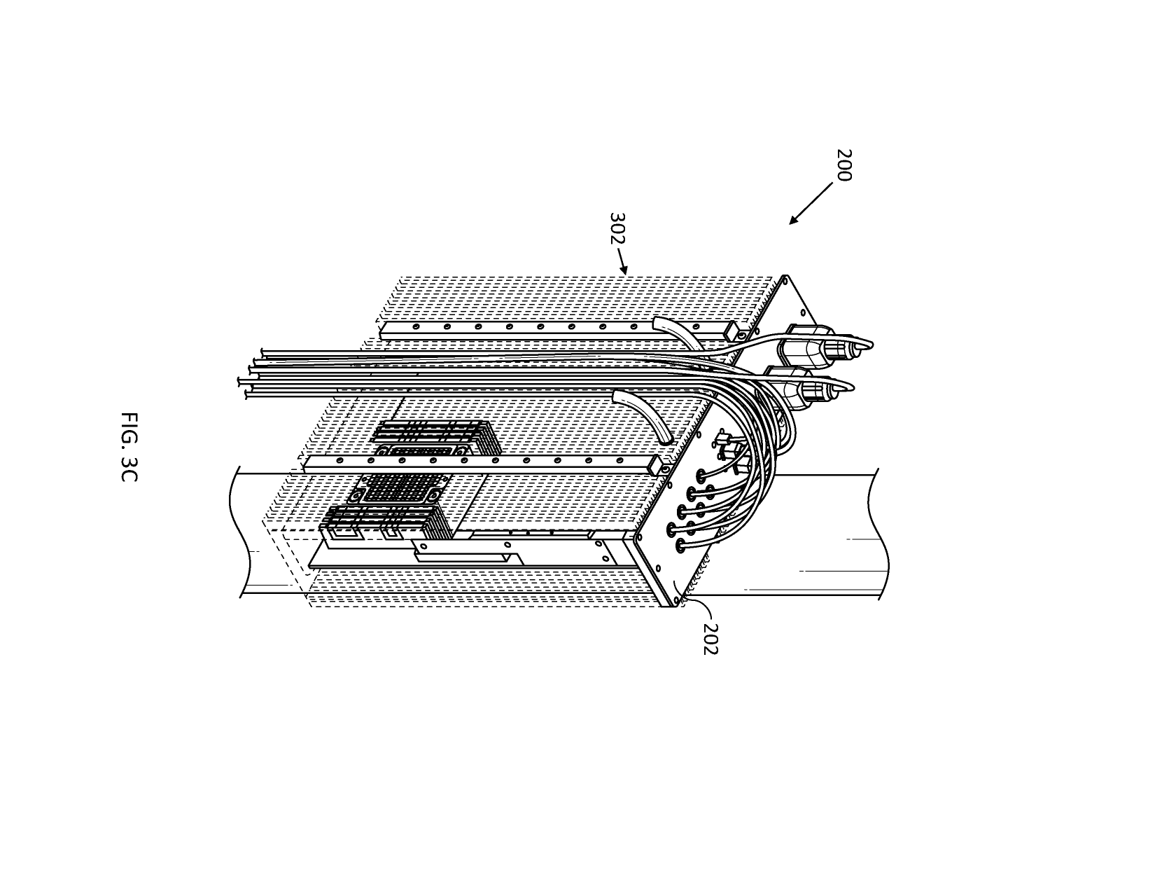

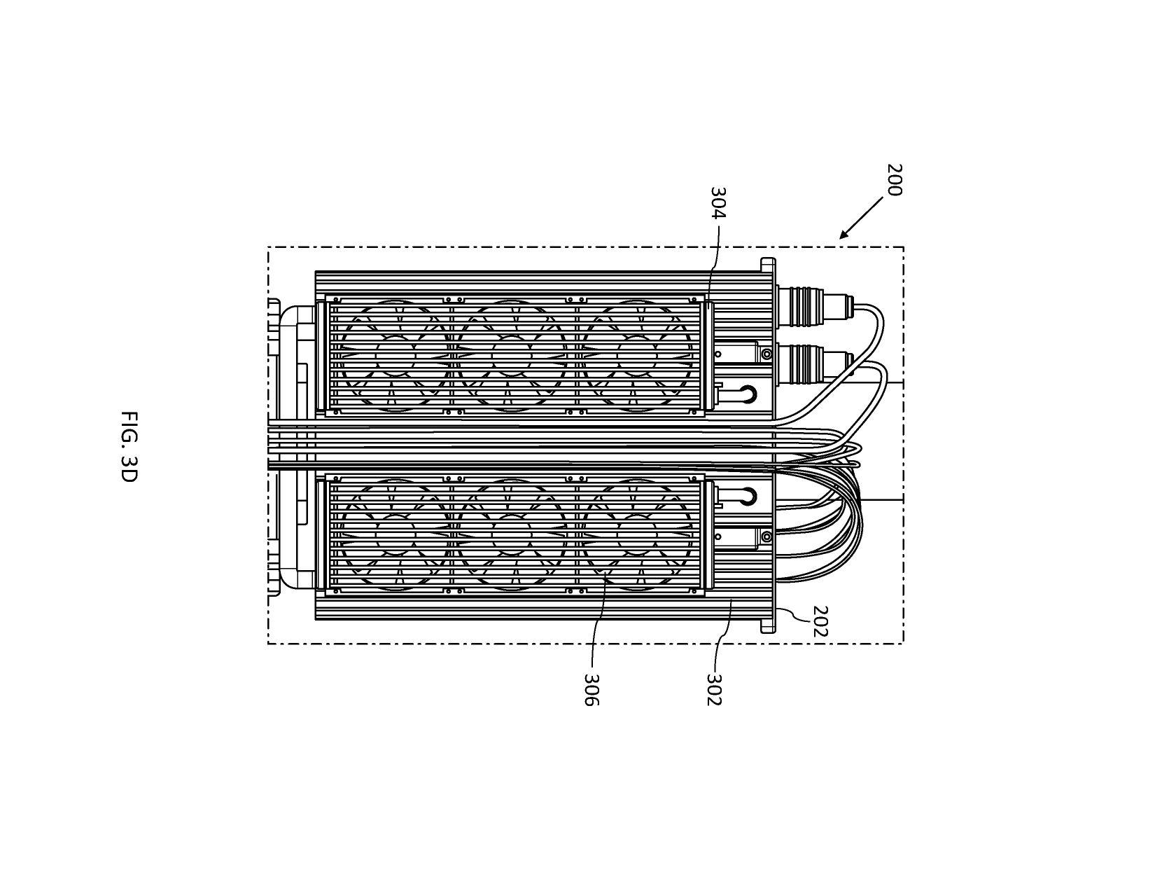

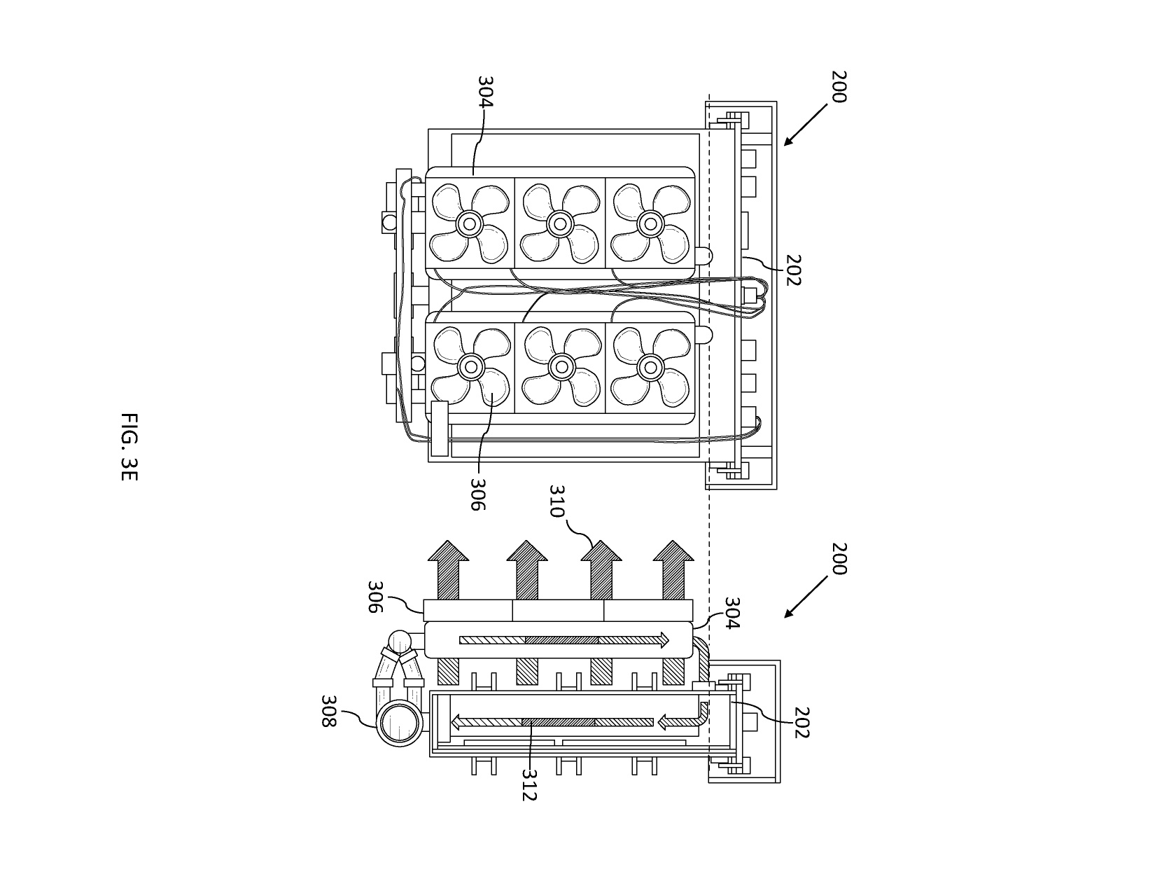

Referring to FIGS. 3A-3E, the enclosure 200 may include one or more cooling mechanisms. In an embodiment, said cooling mechanisms may include one or more of a plurality of cooling fins (the “fins”) 302, one or more radiators 304, one or more fans 306, and/or a combination thereof.

In one or more embodiments, the plurality of fins 302 may be integrally formed on an exterior and/or interior surface of the chassis 202 or attached as a separate component. Further, said fins 302 may be arranged in a parallel configuration along a vertical length of the chassis 202 to increase surface area for heat dissipation. To illustrate, the plurality of fins 302 may increase the surface area of an exterior of the chassis 202 to more effectively transfer heat generated by the electronic components within the chassis 202 to an external environment.

To facilitate transportation of the dielectric fluid within the enclosure 200, embodiments of the chassis 202 may include one or more fluid inputs and/or fluid outputs. Said inputs and/or outputs may enable dielectric fluid to flow out of the chassis 202 through the fluid output, and back into the chassis 202 through the fluid input.

In an embodiment, the one or more radiators 304 may be integrated within the enclosure 200 to enhance heat dissipation. Alternatively, the one or more radiators 304 may be external to the enclosure 200 for maximizing heat transfer between the warmed dielectric coolant and ambient air temperatures.

The one or more radiators 304 may provide additional temperature transfer capability to the enclosure 200 by providing additional surface area for the dielectric fluid to contact. As further shown in FIG. 3E, the one or more radiators 304 may be fluidly connected to the interior space of the chassis 202 via the one or more fluid inputs and/or fluid outputs to facilitate heat transfer from dielectric coolant circulating through the enclosure 200.

In one or more embodiments, the one or more radiators 304 may be connected in series or in parallel between the fluid outlet and inlet.

The enclosure 200 may further comprise, one or more pumps 308 to move the dielectric fluid through the enclosure 200. For instance, the dielectric fluid may exit from a bottom end of the chassis 202 via the one or more fluid outlets, and be directed through the one or more radiators 304, before returning to the interior space of the chassis 202 via the one or more fluid inlets.

While the chassis 202 and/or one or more radiators 304 may achieve passive cooling of the electronic components on the IT Board 204 by transferring heat from such components to the external environment via the dialectic fluid, an active system may be achieved by utilizing the one or more fans 306.

As further shown in FIG. 3E, the one or more fans 306 may be positioned abutting each of the radiators 304 and configured to direct airflow therethrough. The fans 306 may be used in a push or pull configuration to move air through the radiators 304, and in doing so, may also increase airflow over the plurality of fins 302 due to their close proximity to the chassis 202. This configuration may achieve a greater heat transfer rate between the dielectric fluid and the external environment, providing active cooling when higher heat transfer rates are required beyond what passive cooling can achieve.

Referring to FIG. 3E, an airflow path 310 may be established through the enclosure 200, showing the direction of air movement as driven by the fans 306. Ambient air may enter the enclosure 200 and pass laterally through the radiators 304, where heat is absorbed from the dielectric coolant circulating within the enclosure 200. As an example, cool air may enter the one or more radiators 304 before being heated and exhausted out an opposite side of the one or more radiators 304. In an embodiment, the one or more fans 306 may blow air directly on the plurality of cooling fins 302 to accept heat from warmed dielectric coolant within the chassis 202.

A coolant flow path 312 may illustrate the circulation of dielectric fluid as pumped by the one or more pumps 308 through internal channels, demonstrating a vertical circulation pattern within the enclosure 200 generally perpendicular to the airflow path 310.

In one or more embodiments, the one or more radiators 304 may include an internal wall defining a coolant channel between the internal wall and an outer heat exchanger surface. Dielectric fluid may circulate through the coolant channel to transfer heat to the outer heat exchanger surface. In some cases, cooling channels on the one or more radiators 304 may be positioned on an inside of the chassis 202, with the one or more fans 306 positioned on an outside above the plurality of fins 302. Dielectric coolant may be pumped from a bottom portion to a top portion of the one or more radiators 304, from an inlet to an outlet, wherein the one or more fans 306 push air through the plurality of fins 302 and heat is removed from the dielectric fluid as the dielectric fluid is pumped to the outlet of the one or more radiators 304.

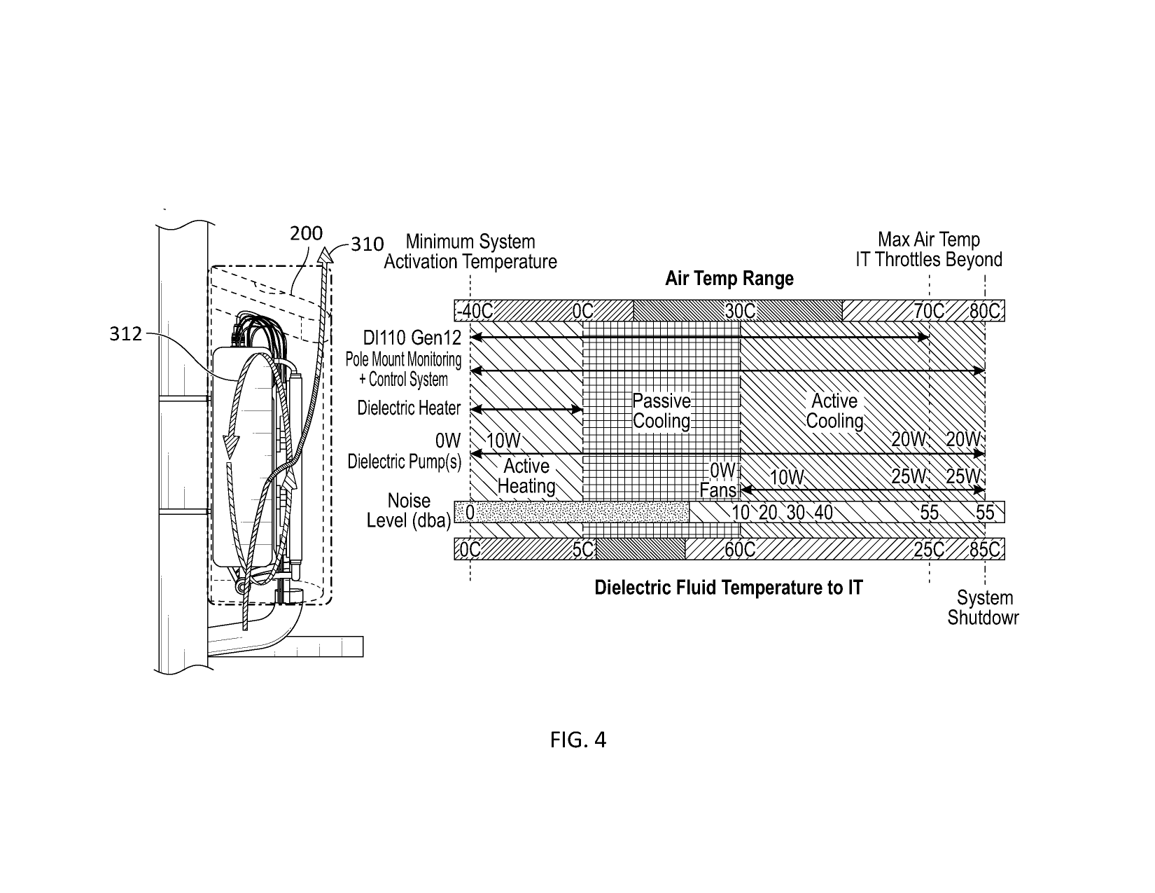

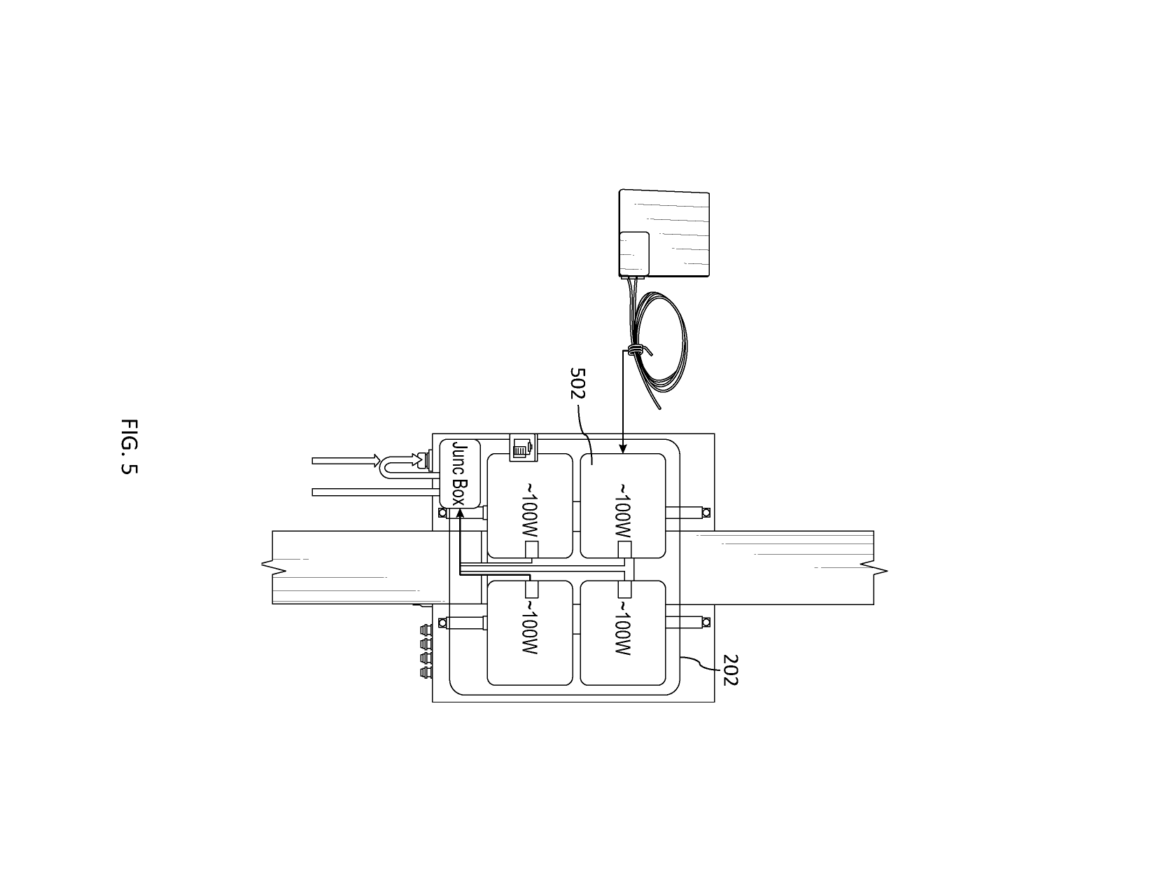

Moving to FIGS. 4 and 5, certain dielectric fluid or air temperature ranges may cause the enclosure 200 to perform one of the following temperature control phases: active heating, passive cooling, or active cooling.

While the aforementioned cooling mechanisms may effectively cool the electronic components disposed on the IT Board 204, in extreme temperatures, the need may arise to heat the IT Board 204. Such temperatures may include outdoor air temperatures below 0°C or dielectric fluid temperatures below 5°C. At extremely low air temperatures (such as at or below -40°C), the electronic components on the IT Board 204 may begin to fail, and the dielectric coolant may become too viscous to effectively move through the enclosure 200. In such instances, one or more heating elements 502 may be used. In an embodiment, such heating elements 502 may abut against the chassis 202.

In one or more embodiments, the enclosure 200 may feature the one or more heating elements 502. Specifically, the one or more heating elements 502 may be disposed between the enclosure 200 and the chassis 202. For instance, said heating elements 502 may be placed directly within the chassis 202. As a non-limiting example, the one or more heating elements 502 may be comprised of four separate elements. However, any alternative number of heating elements may be suitable.

In one or more embodiments, the one or more heating elements 502 may be positioned on an exterior surface of the chassis 202 rather than within the interior space of the chassis 202. Such positioning may provide safety benefits by ensuring that the heat source is not directly in contact with the dielectric fluid. In some aspects, a protective plate may be positioned over the one or more heating elements 502, with insulation disposed below the one or more heating elements 502. This configuration may promote heat transfer into the chassis 202 rather than to the external environment.

Additionally, the one or more heating elements 502 may comprise heater pads rated at approximately 100W each. The one or more heating elements 502 may have AC/DC compatibility, enabling operation with the same voltage as the electronic components to simplify power input. In some cases, the one or more heating elements 502 may include an integral thermostat for temperature regulation.

The one or more heating elements 502 may activate to provide thermal input to the chassis 202, warming the dielectric coolant and to maintain coolant viscosity suitable for circulation via the pumps 308. To illustrate, the one or more heating elements 502 may transfer thermal energy through the walls of the enclosure 200 and/or chassis 202 to the dielectric fluid, which distributes warmth throughout the enclosure 200 to prevent electronic component failure and to maintain operation of the electronic components therein.

Additionally, the one or more heating elements 502 may be communicatively coupled to at least one of an internal temperature sensor, an external temperature sensor, and a controller. For instance, the external temperature sensor may monitor outdoor ambient air temperatures, while the internal temperature sensor monitors dielectric coolant temperature. In one or more embodiments, the internal temperature sensor may be disposed within the interior space of the chassis 202. IN an embodiment, the external temperature sensor may be disposed external to the chassis 202. To illustrate, such an external temperature sensor may be disposed between the chassis 202 and the enclosure 200, or external to the enclosure 200 to more accurately measure ambient temperature.

Upon the outdoor ambient temperature and/or the dielectric coolant temperature dropping below a specific temperature threshold, the external temperature sensor and/or the internal temperature sensor may send a signal to the controller to turn on the one or more heating elements 502.

In an embodiment, the one or more heating elements 502 may work in parallel or in series. For example, when operating in parallel, the one or more heating elements 502 may become operable simultaneously once outdoor ambient temperatures and/or internal dielectric coolant temperatures drop below a specific temperature.

When operating in series, each of the one or more heating elements 502 may become operable at various outdoor ambient temperatures and/or dielectric coolant temperatures, which provides redundancy and distributes power consumption over time, reducing electrical load spikes while maintaining consistent heating performance. As a nonlimiting example, the one or more heating elements 502 may comprise a first, second, third, and fourth mat, wherein the first mat becomes operable at a first temperature, the second mat becomes operable at a second temperature, the third mat becomes operable at a third temperature, and the fourth mat becomes operable at a fourth temperature.

During active heating, the one or more heating elements 502 may emit heat which is then conducted through the walls of the chassis 202 and to the IT Board 204 via the dielectric coolant. Such heat allows the one or more pumps 308 to continue pumping dielectric coolant around the enclosure, which said pumps 308 may do throughout each of the temperature control phases described herein.

As a non-limiting example, the enclosure 200 may rely solely on passive cooling without the need for assistance from the one or more fans 306 or heating elements 502. Passive cooling may be implemented at air temperature ranges of 0°C to 30°C, or at dielectric fluid temperature ranges of 5°C to 60°C. During such phase of cooling, the plurality of fins 302 may passively transfer heat from the dielectric fluid to the ambient environment. During the passive cooling temperature control phase, the one or more pumps 308 may circulate the dielectric coolant to ensure effective heating and cooling of the dielectric coolant as it moves through the enclosure 200.

If a higher rate of heat transfer is required in excess of what passive cooling can achieve, active cooling may be used. As a non-limiting example, active cooling may be utilized at air temperature ranges of 30°C to 80°C, or at dielectric fluid temperature ranges of 60°C to 85°C In such an embodiment, the one or more fans 306 may pull or push air through the one or more radiators 304 to increase the rate of heat transfer between the dielectric fluid and external environment via the one or more radiators 304 and plurality of fins 302.

In one or more embodiments, the cooling enclosure apparatus may include a heater printed circuit board in lieu of, or in addition to, the one or more heating elements 502. Such a heated printed circuit board may be disposed within the interior space of the chassis 202 and submerged in the dielectric fluid.

Positioning the heater printed circuit board within the interior space of the chassis 202 may enable direct thermal contact between the heater printed circuit board and the dielectric fluid, providing improved thermal performance compared to external mounting configurations. The heater printed circuit board may comprise a plurality of resistors (for example, a bank providing greater than 400 watts of heating capacity) configured to generate heat to warm the dielectric fluid within the chassis 202.

The heater printed circuit board may be communicatively coupled to the controller, the internal temperature sensor, and/or the external temperature sensor. In an embodiment, the controller may selectively activate portions of the resistors on the heated circuit board based on temperatures captured by the internal temperature sensor and/or the external temperature sensor.

The plurality of resistors may be configured to be activated in stages at different temperature thresholds to distribute power consumption over time, providing redundancy and reducing electrical load spikes. In some aspects, the heater printed circuit board may provide heating when ambient temperatures drop below 0°C or dielectric fluid temperatures drop below 5°C. At extremely low temperatures (such as -40°C), the heater printed circuit board may prevent component failure and maintain coolant viscosity suitable for circulation via the one or more pumps 308.

Due to concerns over the health of the electronic components in the enclosure 200, such components may be configured to shut down if either the air temperature or dielectric fluid temperature exceeds a predetermined value. As a non-limiting example, such value may be 80°C for air temperature, and/or 85°C for dielectric fluid temperature.

The controller (not depicted) may be used to selectively turn the one or more fans 306 on or off, or adjust the speed of the one or more fans 306, depending on the temperature of the components on the IT Board 204 and/or the temperature of the external environment. For low measured air temperatures, the enclosure 200 may utilize passive cooling as described herein. For high measured air temperatures, the enclosure 200 may utilize active cooling as described herein.

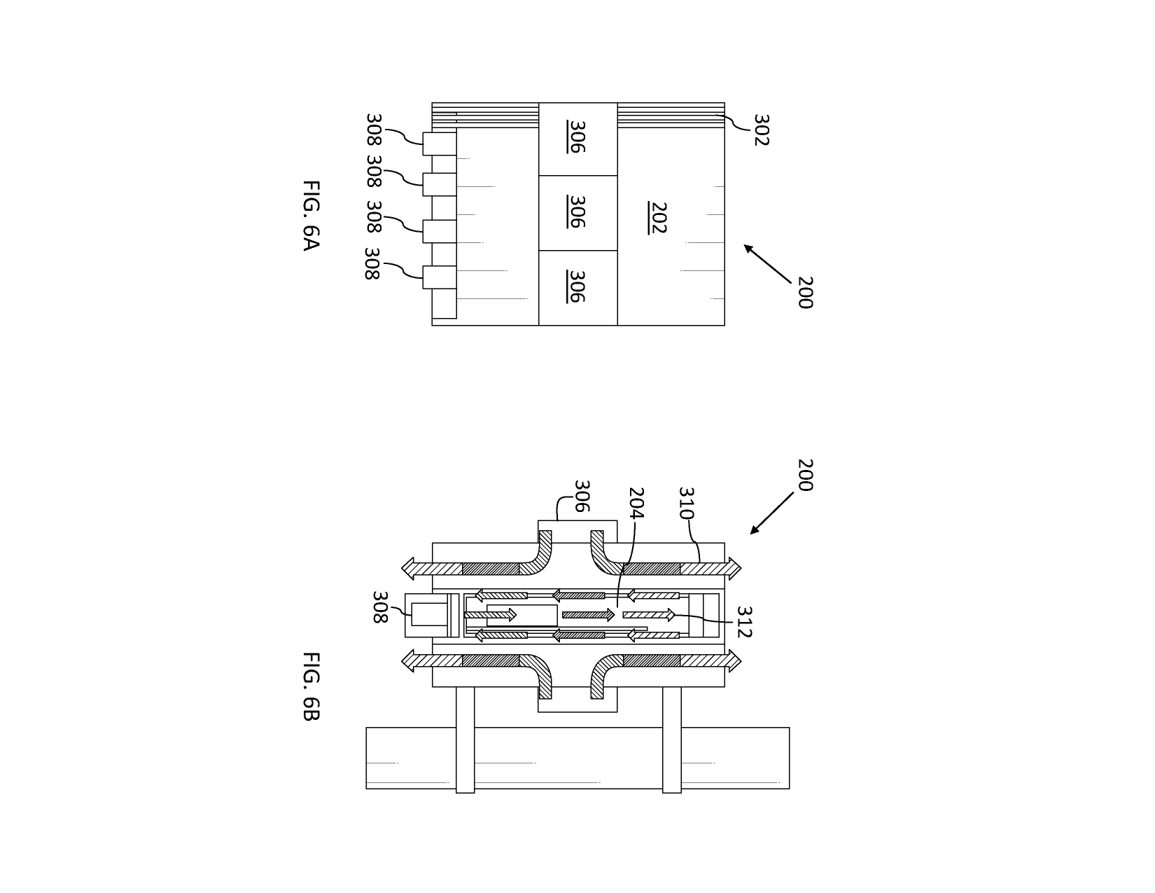

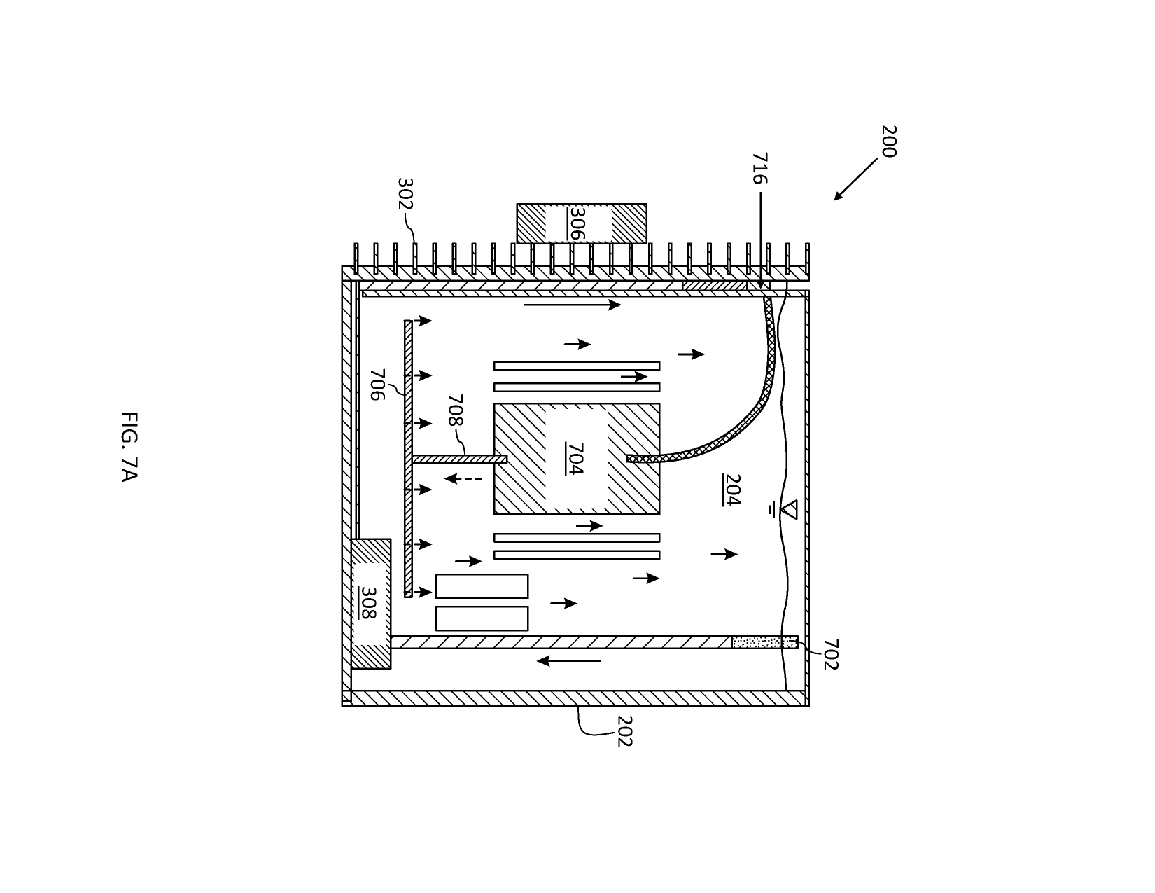

Turning to FIGS. 6A and 6B, an aspect of the present disclosure may involve a different configuration of the one or more fans 306 to achieve the desired cooling without the need for the one or more radiators 304. In such an embodiment, one or more fans 306 may be disposed at any suitable location against one or more sides of the enclosure 200. As such, the one or more fans 306 may transport air into an interior volume of the enclosure 200 and over the plurality of fins 302 where heat is transferred to the air before being exhausted out of the top and/or bottom of the enclosure 200.

To enable the dielectric coolant to efficiently cool the electronic components on the IT Board 204, the IT Board 204 may form a barrier defining one or more channels through which dielectric fluid may flow. In an embodiment, one or more structures, such as a wall, baffle, or barrier, may be used to define the one or more channels. As exemplified in FIG. 6B, one or more pumps 308 may move dielectric fluid over the IT Board 204 and the electronic components thereon. After flowing over said components, the dielectric fluid may then overflow into the one or more channels defined by the IT Board 204, where the dielectric fluid may, with the assistance of gravity, flow back to the one or more pumps 308 where it is then recirculated.

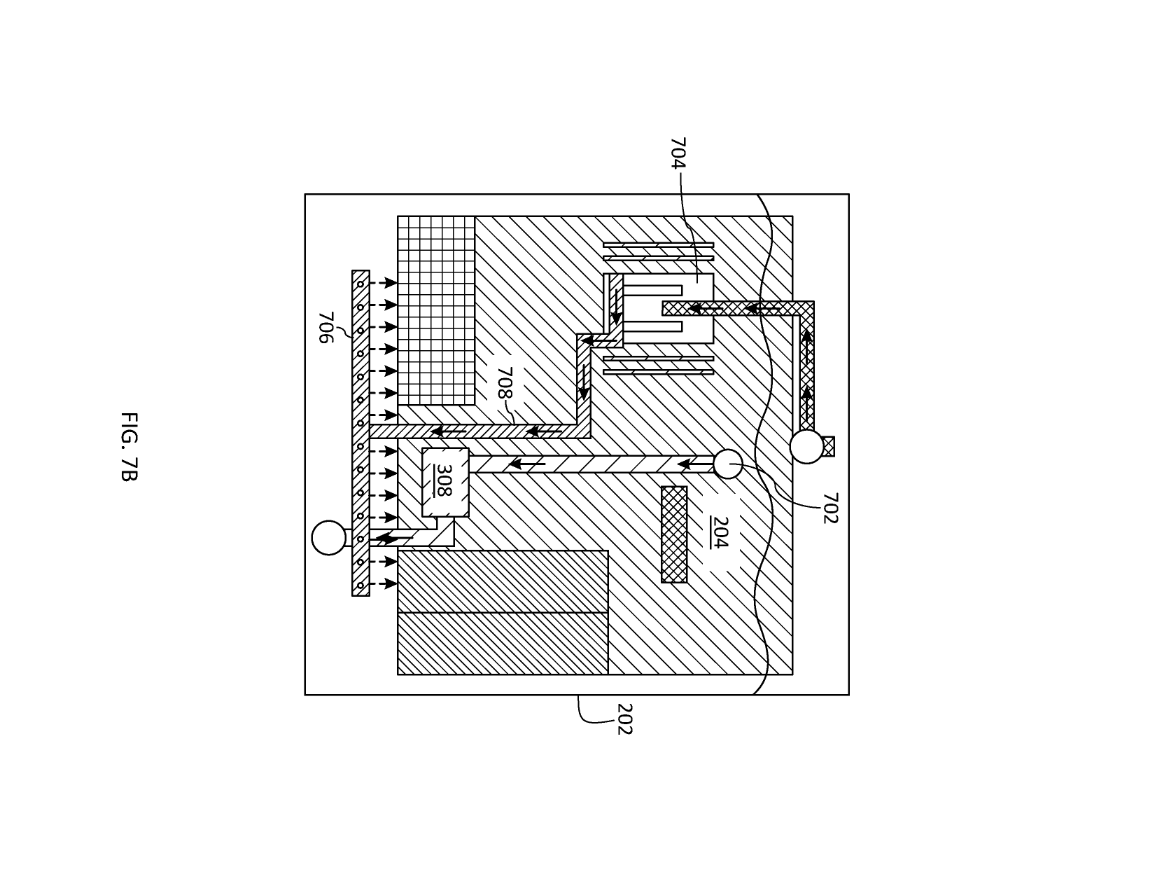

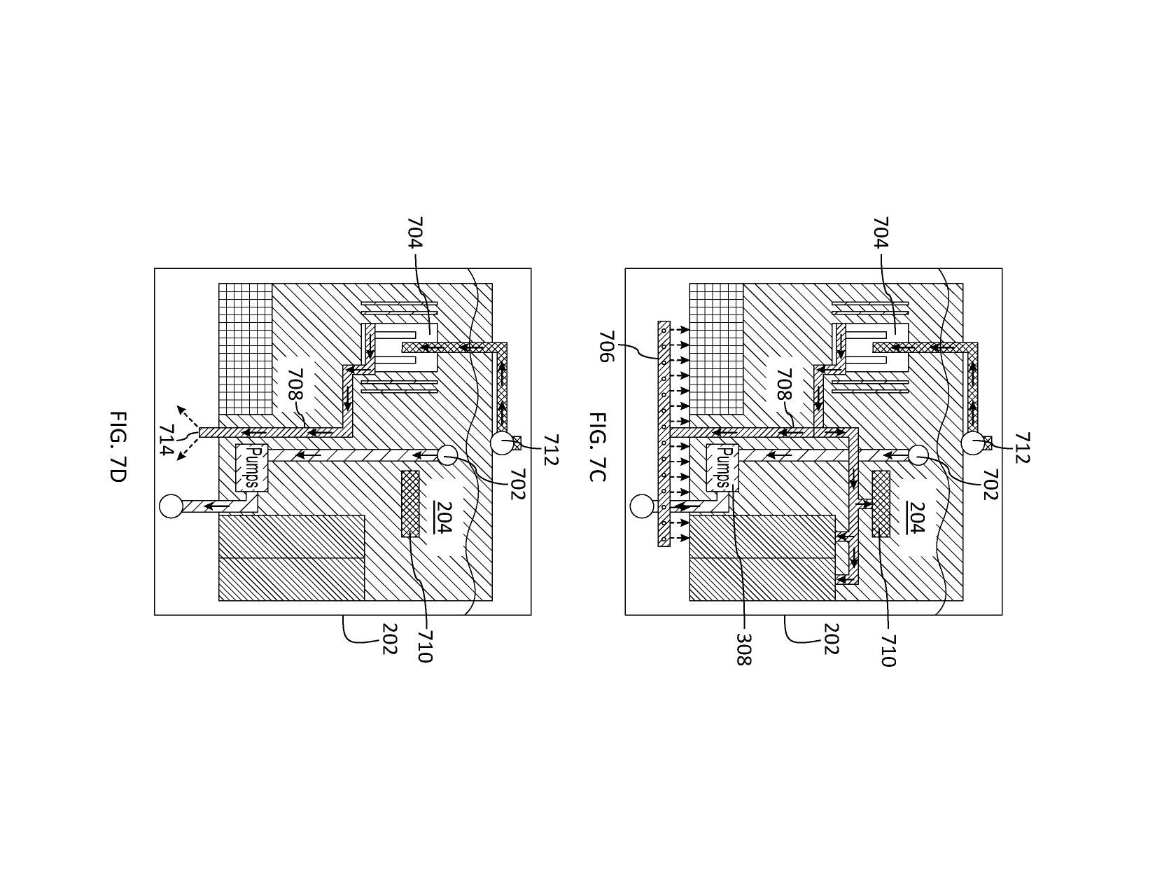

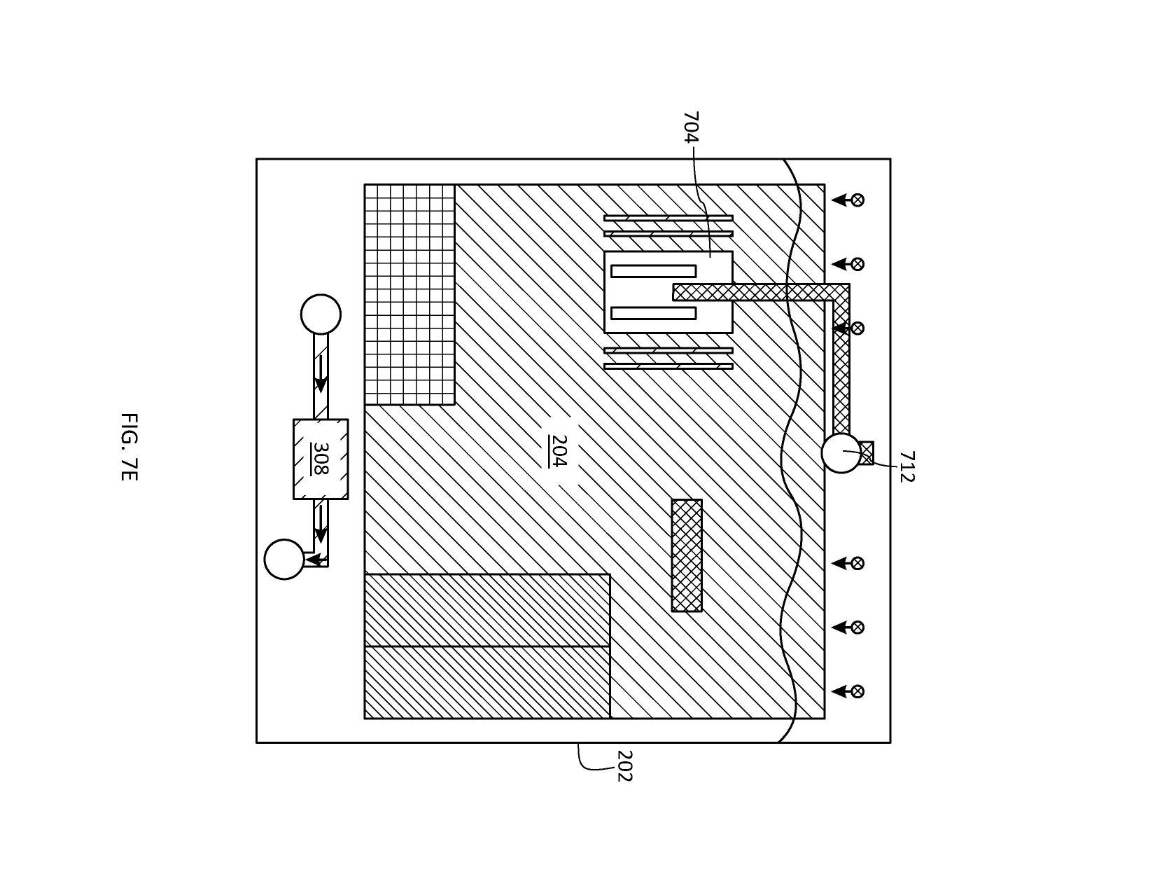

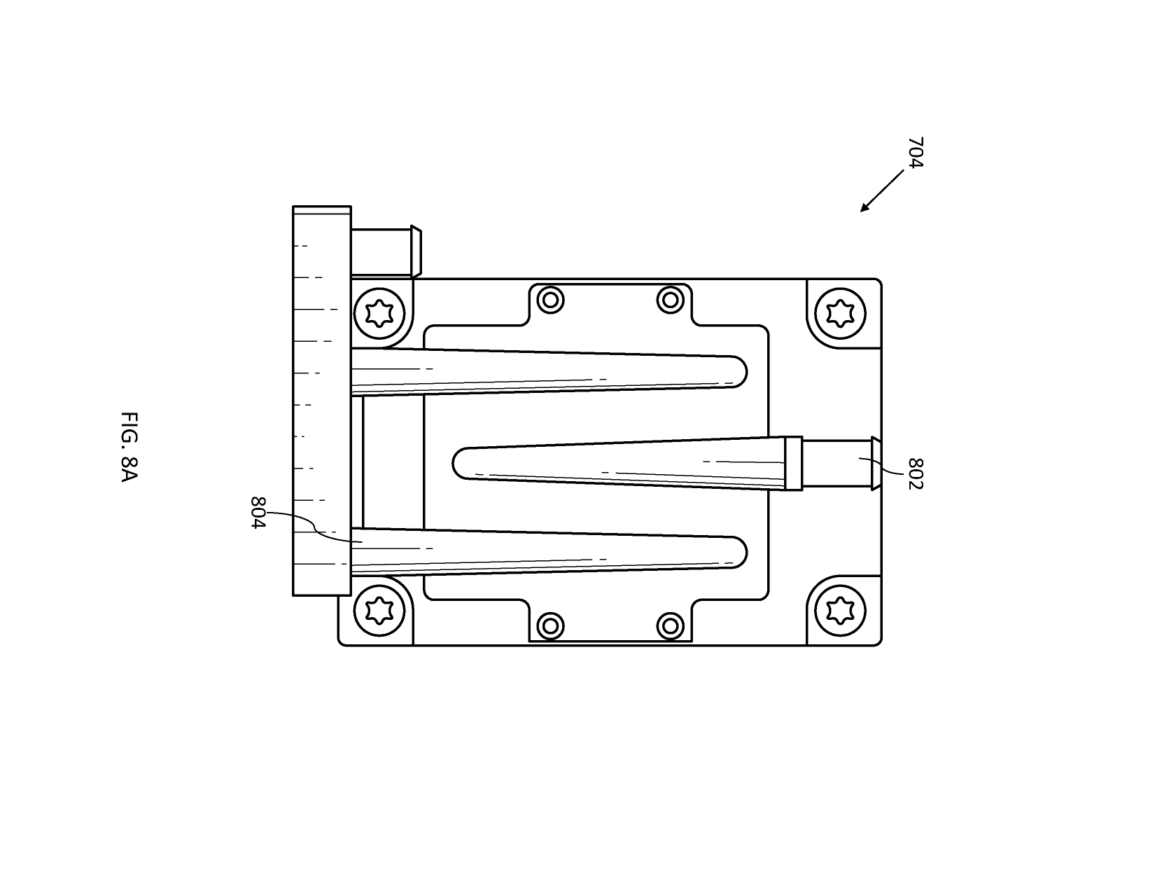

Referring to FIGS. 7A and 7B, aspects of the present disclosure may further relate to a hybrid cooling system for electronic components, particularly suited for high-performance processors and outdoor electronic equipment applications. Such a hybrid cooling system may incorporate the features and aspects of the enclosure 200 described above.

The hybrid cooling system may route coolant via dedicated piping to different areas of the chassis 202 (described in more detail below) to provide targeted cooling for specific components. Such a hybrid cooling system may leverage both passive and active cooling mechanisms. To illustrate, the one or more pumps 308 may circulate dielectric coolant throughout a cooling loop that creates continuous circulation for removing heat from the electronic components on the IT Board 204.

The cooling loop may begin with a coolant inlet 702 that receives warmed dielectric coolant (described in more detail below). From the inlet 702, the warmed coolant may be actively pumped via the one or more pumps 308. For instance, the warmed coolant may be pumped to the one or more radiators 304 and/or a cooling channel defined by an exterior wall of the chassis 202 and the one or more radiators 304 and/or the fins 302. While circulating through the radiator 304 and/or the channel, the coolant may reject heat to the external environment as the one or more fans 306 direct cool air across the radiator 304 and/or channel, necessarily facilitating cooling of the coolant.

In an embodiment, the cooling channel 716 may be positioned at an upper portion of the enclosure 200 adjacent to the chassis 202. The cooling channel 716 may facilitate heat transfer from the dielectric coolant to the ambient environment. In some aspects, the cooling channel 716 may be fluidly connected to the one or more cooling fins 302 and/or the one or more radiators 304 to enable transfer of thermal energy from the dielectric coolant circulating through the enclosure 200.

The cooled dielectric coolant may ultimately be recirculated into the chassis 202, where it thermally interfaces with the electronic components therein, and warms, gradually rising back toward the coolant inlet 702, at which point the cycle begins anew. In an embodiment, the cooled dielectric coolant may be directly routed to one or more heatsinks 704 thermally coupled to specific heat-generating electronic components prior to re-entering the chassis 202.

In an embodiment, the chassis 202 may feature one or more CPUs, or similar heat-generating electronic components (e.g., GPUs, field-programmable gate arrays (FPGAs), application-specific integrated circuits (ASICs), digital signal processors (DSPs), etc.), positioned within the chassis 202 on the IT Board 204. Such a CPU, or similar heat-generating electronic components, may be thermally coupled to the one or more heatsinks 704, establishing a heat transfer path from the electronic component to the heatsink 704.

In one or more embodiments, the heatsink 704 may serve as an intermediate heat transfer device that absorbs thermal energy from the electronic component its thermally coupled to, and transfers said thermal energy to the circulating dielectric coolant. For instance, the one or more pumps 308 may direct dielectric coolant directly to the heatsink 704 via a dedicated piping arrangement. Further, from the heatsink 704, the warmed dielectric coolant may be discharged into the chassis 202 to cool the other electronic components therein.

In an embodiment, the hybrid cooling system may include a coolant distribution manifold (the “manifold”) 706. Such a manifold 706 may receive warmed dielectric coolant from the heatsink 704. To illustrate, dielectric coolant may exit the heatsink 704 via the one or more heatsink outlets to piping 708 in fluid communication with said outlets. The piping 708 may also be in fluid communication with the manifold 706, wherein the manifold 706 evenly distributes warmed coolant to a bottom portion of the interior of the chassis 202 to cool electronic components on the IT Board 204.

Upon entering the bottom portion of the interior of the chassis 202, the dielectric coolant may begin to rise, via natural convection, as it accepts heat from the electronic components on the IT Board 204. This natural convection process may transport the thermal energy away from the heat-generating electronic components within the chassis 202 without requiring external mechanical assistance (e.g., a pump).

The hybrid cooling system may also feature the coolant inlet 702 that receives warmed dielectric coolant as it rises towards the top of the chassis 202. Upon receipt by the coolant inlet 702, the one or more pumps 308 may distribute the warmed coolant to be cooled by the one or more fans 306 and ultimately redistributed to the heatsink 704.

In one or more embodiments, the enclosure 200 may not feature the one or more radiators 304. To illustrate, the chassis 202 may feature the one or more cooling fins 302 extending outwardly from an exterior surface thereof. Further, such a chassis 202 may not include an internal wall defining a coolant channel. In such a configuration, the dielectric coolant within the interior space of the chassis 202 may be circulated by the one or more pumps 308, wherein the coolant flow passes directly along an inside surface of the chassis 202 wall. To increase surface area for heat transfer, the one or more cooling fins 302 may be added to an internal wall of the chassis 202, enabling the dielectric coolant to interface with both the internal fins and the interior surface of the chassis 202 wall as the coolant circulates. Such a configuration may reduce overall size and weight of the enclosure 200 compared to configurations incorporating dedicated coolant channels.

Referring to FIG. 7C, the hybrid cooling system may include additional direct to component cooling along with the heatsink 704. For instance, dielectric coolant may be routed to one or more thermal management components 710 such as heatsinks or cold plates, or alternatively, directly to electronic components disposed upon the IT Board 204. The thermal management components 710 may comprise various configurations including finned heat sinks, microchannel cold plates, vapor chambers, heat pipes, and the like, each selected based on the specific thermal requirements and physical constraints of the target electronic components. These components may be fabricated from high conductive materials such as copper, aluminum, or composite materials to maximize heat transfer efficiency.

In an embodiment, cooled dielectric coolant may be routed directly to the one or more thermal management components 710 from the one or more radiators 304, the cooling channel 716, the fins 302, or a combination thereof, via one or more outlets 712 to cool electronic components thermally coupled thereto. Such an embodiment may establish a parallel cooling circuit where the coolest available dielectric fluid is delivered simultaneously from the one or more outlets 712 to multiple high-priority thermal loads.

As a nonlimiting example, such a parallel cooling circuit may direct dielectric coolant from the one or more outlets 712 to both the heatsink 704 and the one or more thermal management components 710. As a further nonlimiting example, the direct routing may be accomplished through dedicated supply lines, such as the piping 708, that maintain coolant temperature and/or flow rate to each of the heatsink 704 and the one or more thermal management components 710. Flow control devices such as valves or flow restrictors may be incorporated to balance coolant distribution among the heatsink 704 and the one or more thermal management components 710 based on the respective thermal loads and cooling requirements of the electronic components thermally coupled thereto. The parallel cooling approach may ensure that each high-heat component receives coolant at substantially the same temperature, preventing thermal performance degradation that could occur if said components were cooled in series with progressively warmer coolant.

In an embodiment, the piping 708 may deliver warmed dielectric coolant from the heatsink 704 to the one or more thermal management components 710 in series. This series cooling configuration may utilize the heat absorbed by the dielectric coolant flowing from a primary heatsink 704 to provide preheated coolant to secondary thermal management components 710. While the coolant temperature is elevated compared to the parallel cooling approach, the warmed coolant may still provide adequate cooling for components with moderate thermal requirements while maximizing overall system thermal efficiency by utilizing the available thermal capacity of the coolant.

In such an embodiment, the piping 708 may include two or more branches for delivering coolant from the heatsink 704 to the manifold 706 and the one or more thermal management components 710. Such a branched piping system may incorporate flow splitting devices, such as tee fittings, and the like, that divide dielectric coolant flow according to the thermal requirements of the electronic components on the IT Board 204 and those coupled to the thermal management components 710. Flow balancing may be achieved through pipe sizing, or adjustable flow control valves that ensure appropriate coolant delivery to each branch while maintaining system pressure and flow stability.

Such a configuration is beneficial for cooling electronic components having a moderate thermal output relative to the electronic components thermally coupled to the heatsink 704. Moderate thermal output components may include DIMMs, NICs, NVMe drives, PSUs, or the like that generate heat levels lower than primary processors but still require active cooling for reliable operation.

In an embodiment, dielectric coolant exiting the heatsink 704 may be routed to the manifold 706 via the piping 708. As a nonlimiting example, the manifold 706 may be disposed towards a bottom of the chassis 202, such that coolant being delivered to the manifold 706 from the heatsink 704 exits the manifold 706 into the bottom of the chassis 202. Subsequently, said coolant may rise towards a top of the chassis 202 via natural convection as it received thermal energy from the electronic components disposed upon the IT Board 204.

Turning to FIG. 7D, the hybrid cooling system may exclude the manifold 706. In an embodiment, the piping 708 may route warmed dielectric to the bottom portion of the interior of the chassis 202 to cool electronic components on the IT Board 204. Similar to above, delivering dielectric coolant to the bottom of the chassis 202 may leverage natural convection flow patterns to cool electronic components situated on the IT Board 204. As the coolant enters the lower portion of the chassis 202, it begins to absorb additional thermal energy from electronic components positioned on the IT Board 204, causing the coolant temperature to increase, reducing its density and creating buoyant forces driving the coolant upwards towards the coolant inlet 702 via natural convection.

To illustrate, the piping 708 may feature one or more discharge points 714 that enable dielectric coolant to directly enter the chassis 202, wherein the coolant may contact and cool electronic components therein.

In one or more embodiments, warmed dielectric coolant exiting the heatsink 704 may be directed to the one or more discharge points 714 via the piping 708, wherein said coolant retains sufficient cooling capacity to effectively manage the thermal requirements of the remaining electronic components within the chassis 202.

In an embodiment, cooled dielectric coolant may be routed directly to the bottom of the chassis 202 from the one or more outlets 712. Thus, the coolest available dielectric coolant may bypass the heatsink 704 and be directly routed to the interior of the chassis 202. Such a configuration may maximize the cooling potential for all electronic components within the chassis 202 by providing dielectric coolant at substantially the same temperature as the heatsink 704 to all electronic components within the chassis 202.

In some embodiments, a parallel cooling circuit may be formed, wherein warmed coolant from the heatsink 704, and cooled dielectric coolant from the outlets 712 may enter the bottom of the chassis 202.

The discharge points 714 may comprise nozzles, spray heads, open-ended tubes, or the like, that direct coolant flow onto specific component surfaces or heat-generating regions. Said discharge points 714 may be optimized through nozzle design, flow rate control, or positioning to ensure adequate coolant coverage while minimizing fluid waste or unwanted cooling of temperature-sensitive components.

The discharge points 714 may be particularly effective for delivering coolant to electronic components with irregular geometries, multiple heat sources, or accessibility constraints. The direct coolant contact enhances heat transfer compared to indirect cooling methods, enabling effective thermal management of high-density component arrays or specialized electronic packages. In an embodiment, the discharged coolant may drain into the chassis 202 for secondary cooling of adjacent components through natural convection.

Referring to FIG. 7E, the hybrid cooling system may exclude both the manifold 706 and the piping 708. The absence of both the manifold 706 and piping 708 reduces system complexity while maintaining effective thermal management of the electronic components within the chassis 202.

For example, warmed dielectric coolant may enter the interior of the chassis 202 directly from the heatsink 704. To illustrate, coolant may overflow from the heatsink 704 and enter the interior of the chassis 202 without requiring separate piping. Such direct transfer of coolant may occur once the heatsink 704 reaches a coolant capacity, allowing excess warmed dielectric fluid to cascade or overflow into the surrounding chassis 202 interior.

Coolant overflow from the heatsink 704 into the chassis 202 may occur through gravity-driven fluid dynamics, where the heatsink 704 maintains a predetermined coolant level during normal operation, and when coolant flow rates exceed the retention capacity of the heatsink 704 or when thermal loads increase coolant expansion, the excess fluid naturally spills over designated overflow edges or through specifically designed overflow apertures (described in more detail below) integrated into the heatsink 704.

In an embodiment, the direct overflow configuration creates a cascading coolant system where the primary heatsink 704 serves as both a cooling device for the electronic component its thermally coupled to, as well as, a distribution point for secondary cooling throughout the chassis 202. The warmed coolant exiting the heatsink 704 retains significant cooling capacity despite having absorbed thermal energy from the electronic component coupled thereto, enabling effective thermal management of components with moderate heat generation rates.

The overflowing coolant, upon entering the interior of the chassis 202 may circulate throughout the chassis 202 via natural convection to create a passive thermal management system that operates without mechanical assistance, as previously described. The warmed coolant entering the chassis 202 creates density gradients that drive natural convection patterns, with heated coolant rising toward the upper regions of the chassis 202 and cooler dielectric coolant settling toward the lower regions, establishing continuous fluid motion enhancing heat transfer from electronic components throughout the interior of the chassis 202.

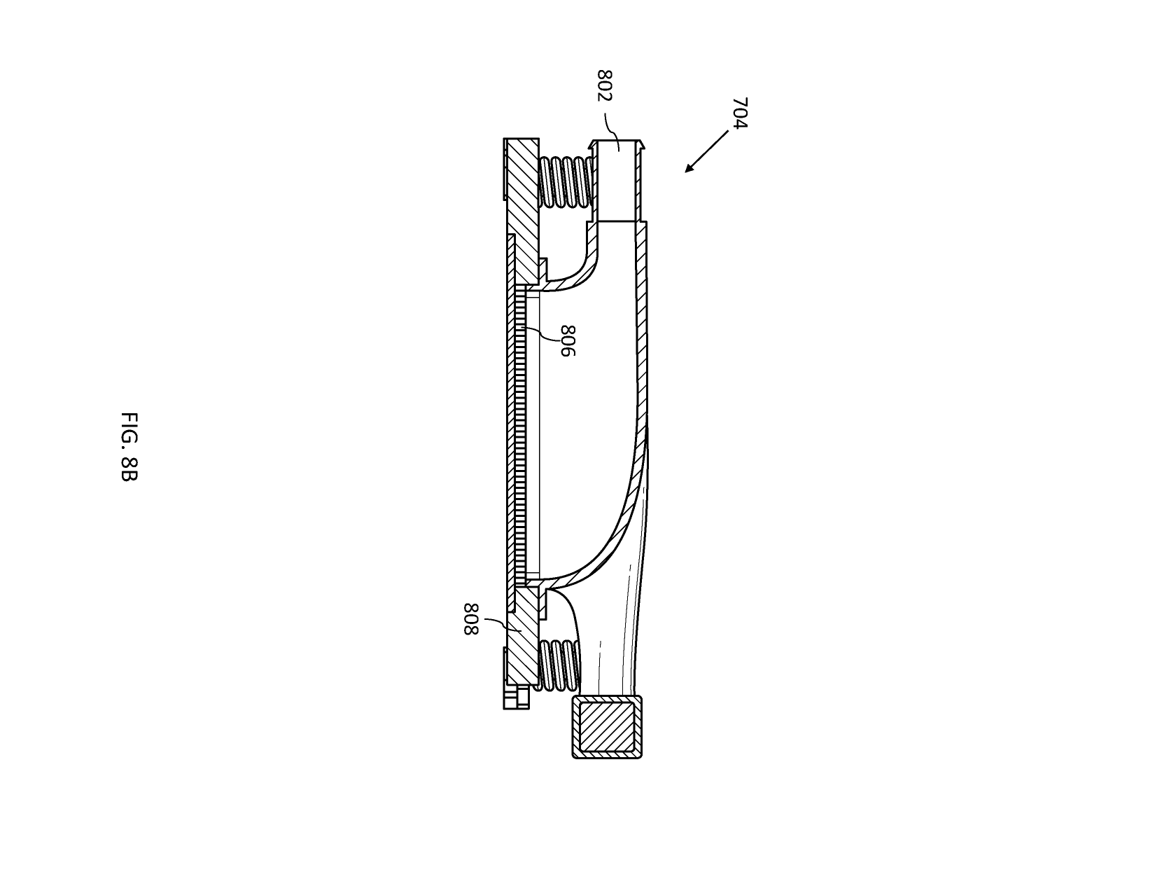

Moving to FIG. 8A, the heatsink 704 may include one or more heatsink inlets 802 and/or one or more heatsink outlets 804. For instance, coolant returning from the outlet 712 may be directly distributed to the heatsink 704 at the one or more heatsink inlets 802 to ensure said heatsink 704 receives the coolest dielectric coolant first. Such a configuration may be desirable for cooling electronic components within the chassis 202 with high thermal output (e.g., a CPU).

Upon receipt of the cooled dielectric coolant via the one or more heatsink inlets 802, the dielectric coolant may be distributed amongst a plurality of cooling fins 806 extending outward from a base 808 of the heatsink 704 to achieve significant surface area enhancement compared to conventional pinned heatsink designs. As a non-limiting example, the heatsink 704 may feature one or more slotted inlets 902 designed to evenly distribute dielectric coolant across the plurality of cooling fins 806. To illustrate, cooled dielectric coolant entering the heatsink 704 via the one or more heatsink inlets 802 may subsequently travel to the one or more slotted inlets 902 prior to being distributed to the plurality of cooling fins 806.

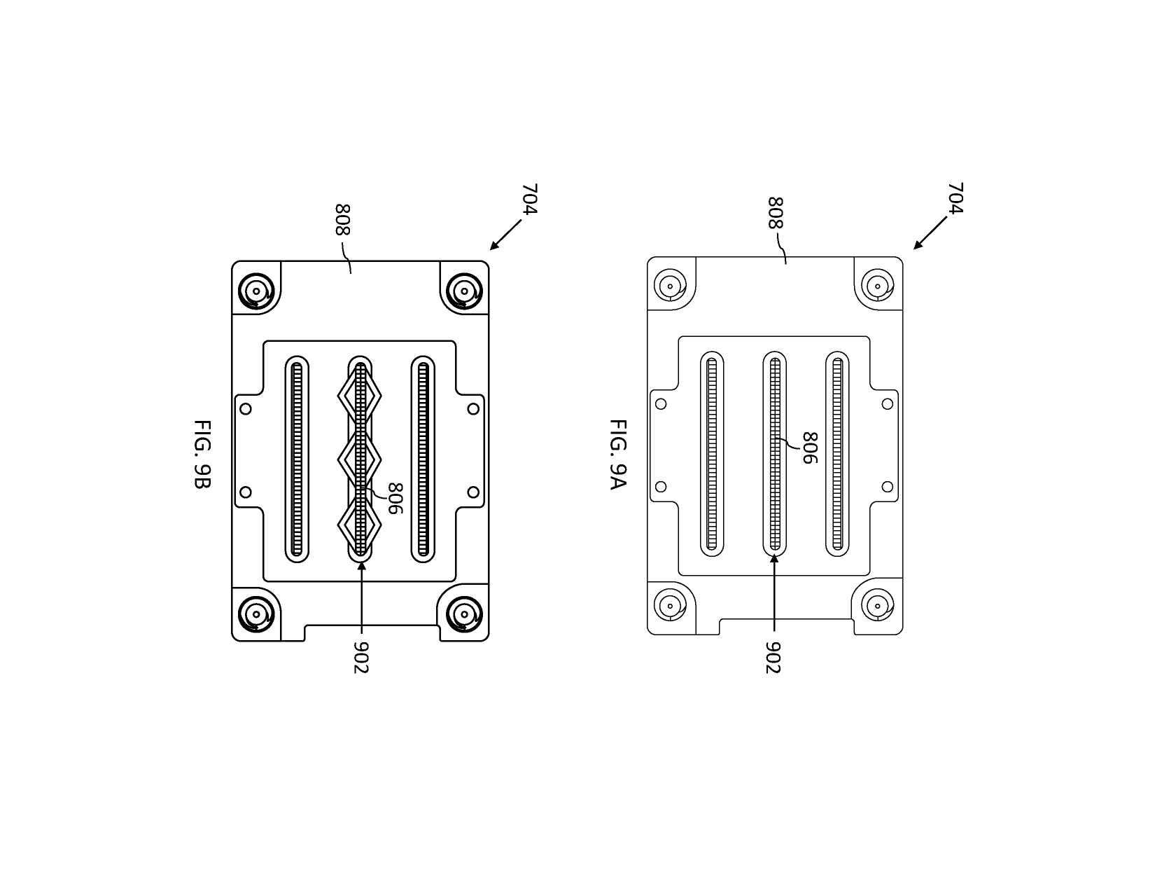

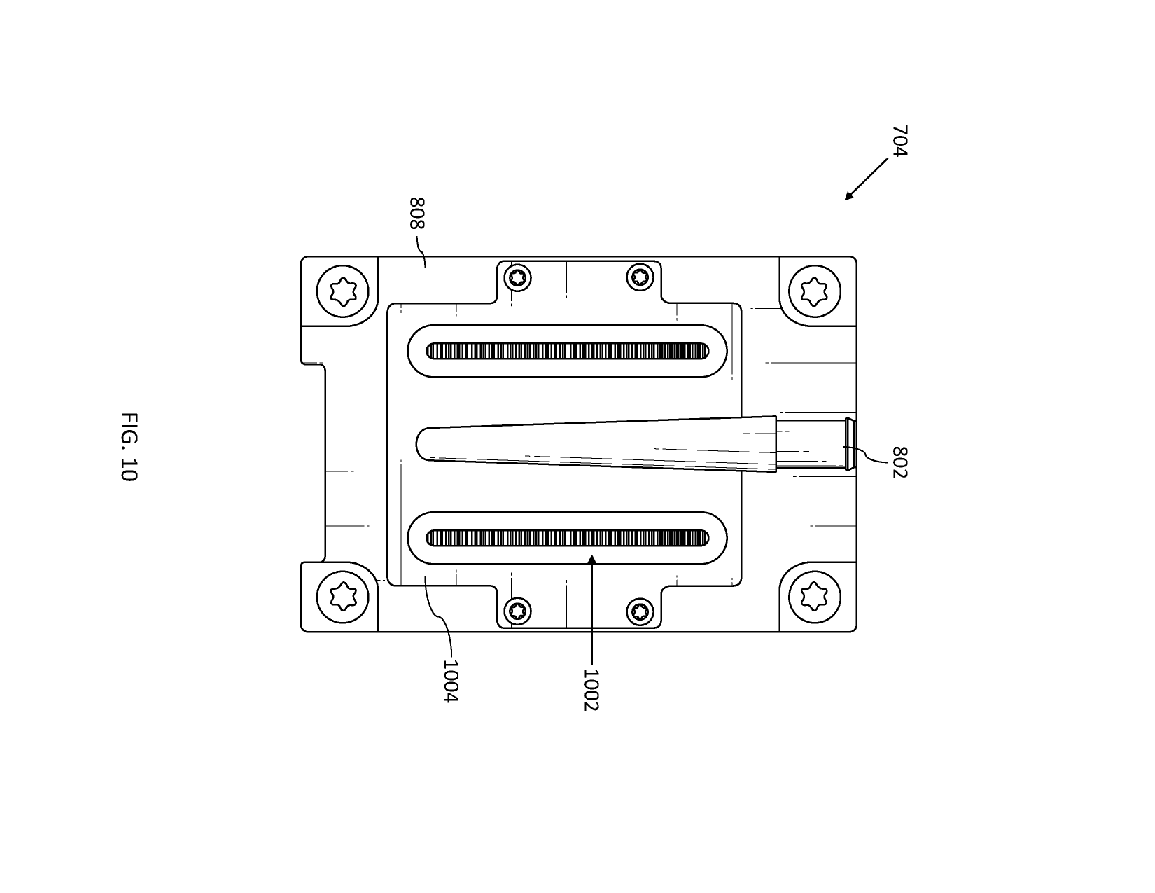

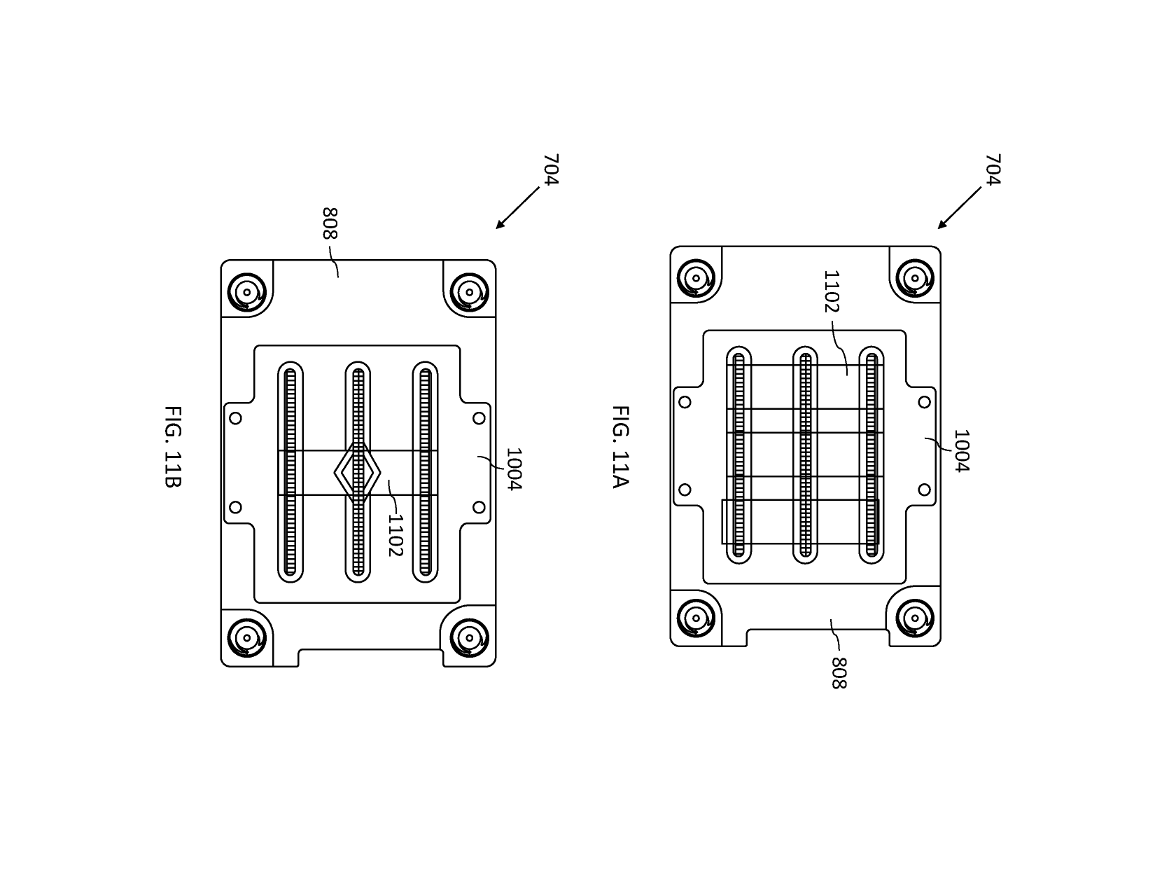

As an example, the one or more slotted inlets 902 may comprise three elongated inlets extending across the length of the heatsink 704 (as illustrated in FIGS. 9A and 9B). In such an example, the three inlets may be evenly spaced to facilitate even distribution of dielectric coolant across the plurality of cooling fins 806.

In an embodiment, the slotted inlets 902 may provide controlled fluid distribution by creating multiple discrete entry points along the length and/or width of the heatsink 704. Each of the slotted inlets 902 of the heatsink 704 may be dimensioned to regulate flow rates of dielectric coolant exiting said inlets 902 while ensuring uniform dielectric coolant delivery across the plurality of cooling fins 806.

In one or more embodiments, the slotted inlets 902 may be positioned at predetermined intervals to correspond with the spacing of the plurality of cooling fins 806, to optimize dielectric coolant contact with each individual cooling fin.

In an embodiment, the slotted inlets 902 may be comprised of elongated apertures extending across a substantial portion of the heatsink 704 length and/or width, which allows dielectric coolant to contact the plurality of cooling fins 806 simultaneously rather than sequentially. Such parallel distribution of dielectric coolant via the slotted inlets 902 minimizes pressure drops across the heatsink 704 while maximizing heat transfer efficiency by ensuring that each of the plurality of cooling fins 806 receive adequate dielectric coolant flow.

The geometry of the one or more slotted inlets 902, including width, length, and depth, can be optimized based on the specific thermal requirements of the electronic components thermally coupled thereto. For example, narrower slots may provide higher coolant velocity and enhanced heat transfer coefficients, whereas wider slots accommodate higher flow rates for electronic components with greater thermal output.

Furthermore, the one or more slotted inlets 902 may be formed into various shapes depending on desired flow characteristics. For instance, the one or more slotted inlets 902 may be configured into a straight line shape (as depicted in FIG. 9A) to provide an even distribution of dielectric coolant across the plurality of cooling fins 806.

In one or more embodiments, the one or more slotted inlets 902 may be formed into various polygonal shapes (as depicted in FIG. 9B) to increase dielectric coolant distribution to portions of the plurality of cooling fins 806 requiring increased cooling capabilities.

The base 808 of the heatsink 704 may receive heat from the electronic component thermally coupled thereto, wherein the heat is subsequently distributed amongst the plurality of cooling fins 806. As the dielectric coolant flows through the plurality of cooling fins 806, said coolant removes heat from the cooling fins 806, and exits the heatsink 704 via the one or more heatsink outlets 804 (described in more detail below).

Turning to FIG, 10, the heatsink 704 may feature slotted exit holes 1002 positioned to allow coolant overflow, thereby enabling cooling of additional electronic components positioned on the IT Board 204.

In one example, the one or more slotted exit holes 1002 may facilitate controlled overflow of dielectric coolant from the heatsink 704 into the chassis 202. To illustrate, upon receiving heat from the plurality of cooling fins 806, the warmed dielectric coolant may spill out of the heatsink 704 via the one or more slotted exit holes 1002 and into the chassis 202.

In an embodiment, the slotted exit holes 1002 may be strategically positioned and dimensioned to regulate the overflow rate and distribution pattern of the heated coolant. For instance, the exit holes 1002 may be located at predetermined heights and/or widths along the heatsink 704 to enable heated coolant to cascade into the chassis 202 and prevent uneven cooling distribution.

Similar to the one or more slotted inlets 902, the geometry of the slotted exit holes 1002, including slot width, length, and spacing, may be tailored to match the thermal load characteristics of both the heatsink 704 and electronic components disposed within the chassis 202. To illustrate, higher thermal loads of the electronic components within the chassis 202 may require larger or more numerous exit holes 1002 to accommodate increased coolant flow rates, whereas lower thermal applications may utilize smaller, more restrictive exit holes 1002 to maintain adequate residence time within the heatsink 704 for effective heat transfer.

Similar to the embodiments described above, the warmed dielectric coolant exiting the one or more slotted exit holes 1002 may begin to rise, via natural convection, as said coolant interfaces with, and accepts heat from, heat-emitting electronic components within the chassis 202.

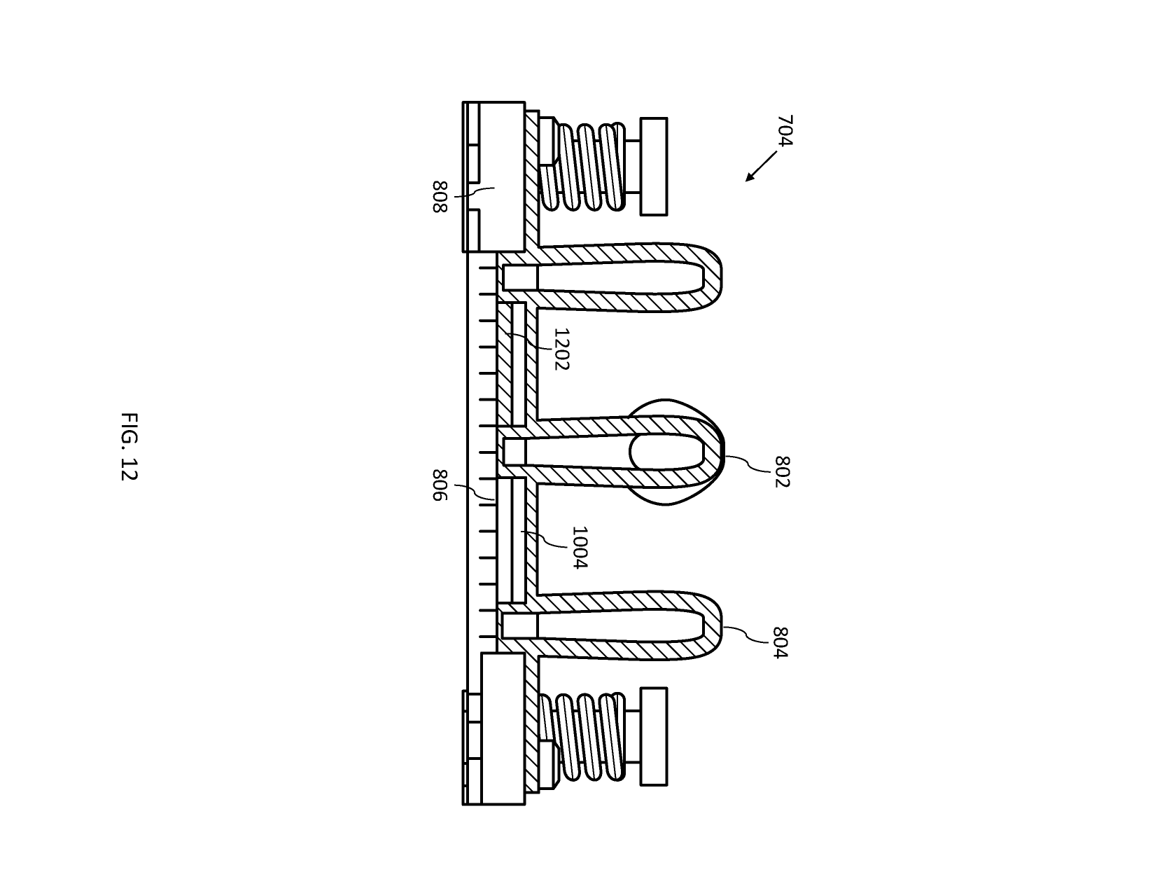

In an embodiment, one or more dies 1102 may be placed over the one or more slotted inlets 902 and/or the one or more slotted exit holes 1002. Such dies 1102 may be configured to accommodate off-center heat sources, such as a single die (as depicted in FIG. 11B) or multiple dies (as depicted in FIG. 11A) for heat sources positioned at various locations on an electronic component. The geometry and positioning of the dies 1102 may be tailored to different thermal management needs based on the specific heat distribution characteristics of the electronic components thermally coupled to the heatsink 704.

In one or more embodiments, the geometry of the dies 1102 may be modified adjacent to heat generating electronic components to provide extra coolant flow to the hottest parts of said components. For instance, dies 1102 positioned over the slotted inlet holes 902 may include apertures or channels that direct increased dielectric coolant flow toward regions of the electronic component exhibiting higher thermal output. Similarly, dies 1102 positioned over the slotted exit holes 1002 may be configured to facilitate enhanced coolant drainage from high-temperature zones, thereby improving overall heat transfer efficiency.

In one or more embodiments, the dies 1102 may be configured for a single heat source on the electronic component. Such a configuration may provide an alternative to configurations designed for multiple heat sources or heat sources in different positions. The single heat source configuration may concentrate coolant flow toward a centralized thermal load, maximizing cooling efficiency for electronic components with a dominant heat-generating region. In other embodiments, the dies 1102 may be configured to address multiple heat sources distributed across the electronic component, with the die geometry optimized to balance coolant distribution among the various heat-generating regions.

Additionally, the dielectric coolant may be a two-phase coolant. Meaning, as the coolant receives heat from the electronic components within the chassis 202, the coolant may transform into a vapor that rises towards the coolant inlet 702. As the vapor travels towards the coolant inlet 702, the vapor may be transferred outside of the chassis 202, where it condenses and returns to a liquid state. Such a design may obviate the need for a pump, as the two-phase coolant utilizes a natural convection cycle to continuously cool the electronic components within the chassis 202.

In one embodiment, the heatsink base 808 may be comprised of a conductive material, such as copper. In another embodiment, the base 808 may feature an integrated stiffening bolster 1004 to enhance heat transfer from the base 808 while maintaining adequate clamping force and flatness against the electronic component thermally coupled to the heatsink 704.

In an embodiment, the integrated stiffening bolster 1004 may be a rigid structural element to prevent deformation of the heatsink base 808 under clamping loads. Such a stiffening bolster 1004 may ensure that the thermal interface contact between the heatsink base 808 and the electronic component surface is consistent. Preventing the base 808 from deforming under clamping forces may prevent air gaps from forming which necessarily improves thermal contact and heat transfer efficiency between the heatsink 704 and the electronic component thermally coupled thereto.

In certain embodiments, the heatsink 704 may have a compact height such that its vertical profile is reduced relative to conventional heatsinks. Such a configuration may enable the heatsink 704 to fit within space-constrained environments while still providing effective thermal dissipation. The compact height configuration may include fins, pins, or the like to maximize surface area within the limited vertical profile. Such a low profile design enables the heatsink 704 to be integrated into low-profile electronic devices, enclosures, or assemblies where space is limited.

Moreover, the thermal coupling between the heatsink 704 and the electronic components may be facilitated through thermal interface materials (TIMs) such as thermal pads, thermal grease, phase-change materials, and the like. For example, these TIMs may fill microscopic air gaps between the surfaces of the electronic components and the heatsink 704, significantly improving heat transfer efficiency.

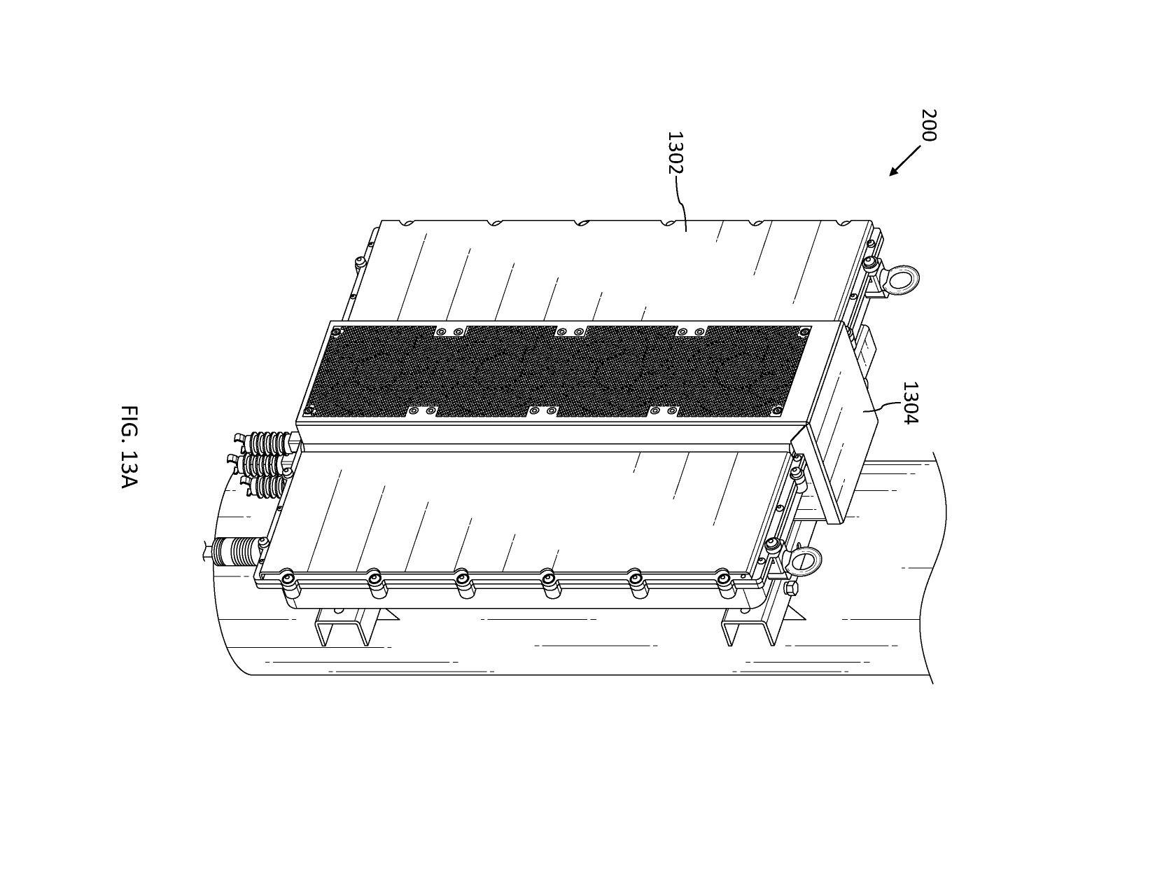

Referring to FIG. 12, one or more foam gaskets 1202 may be positioned between the top of the plurality of cooling fins 806 and the bolster plate 1004 to prevent deformation of said cooling fins 806 while under clamping forces from the stiff metal bolster plate 1004. In an embodiment, the one or more foam gaskets 1202 may prevent coolant from bypassing over the top of the cooling fins 806.

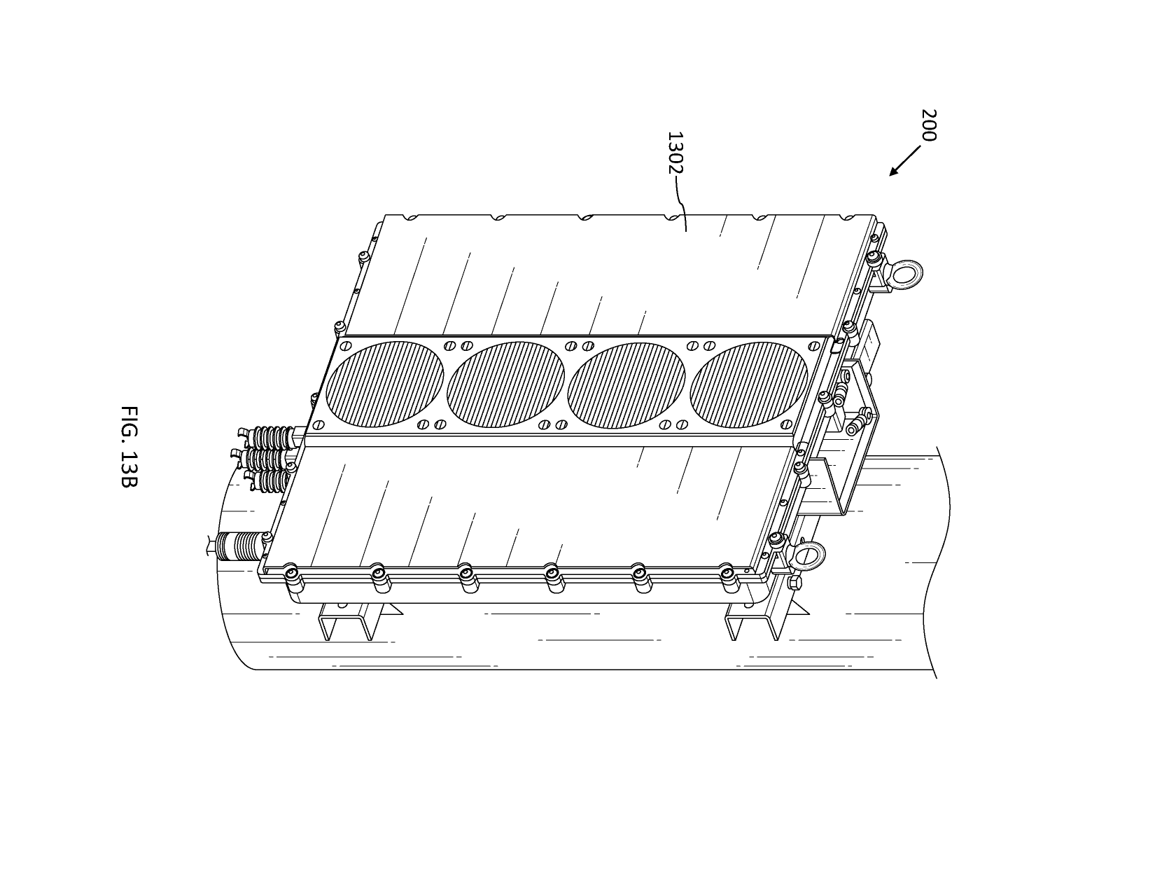

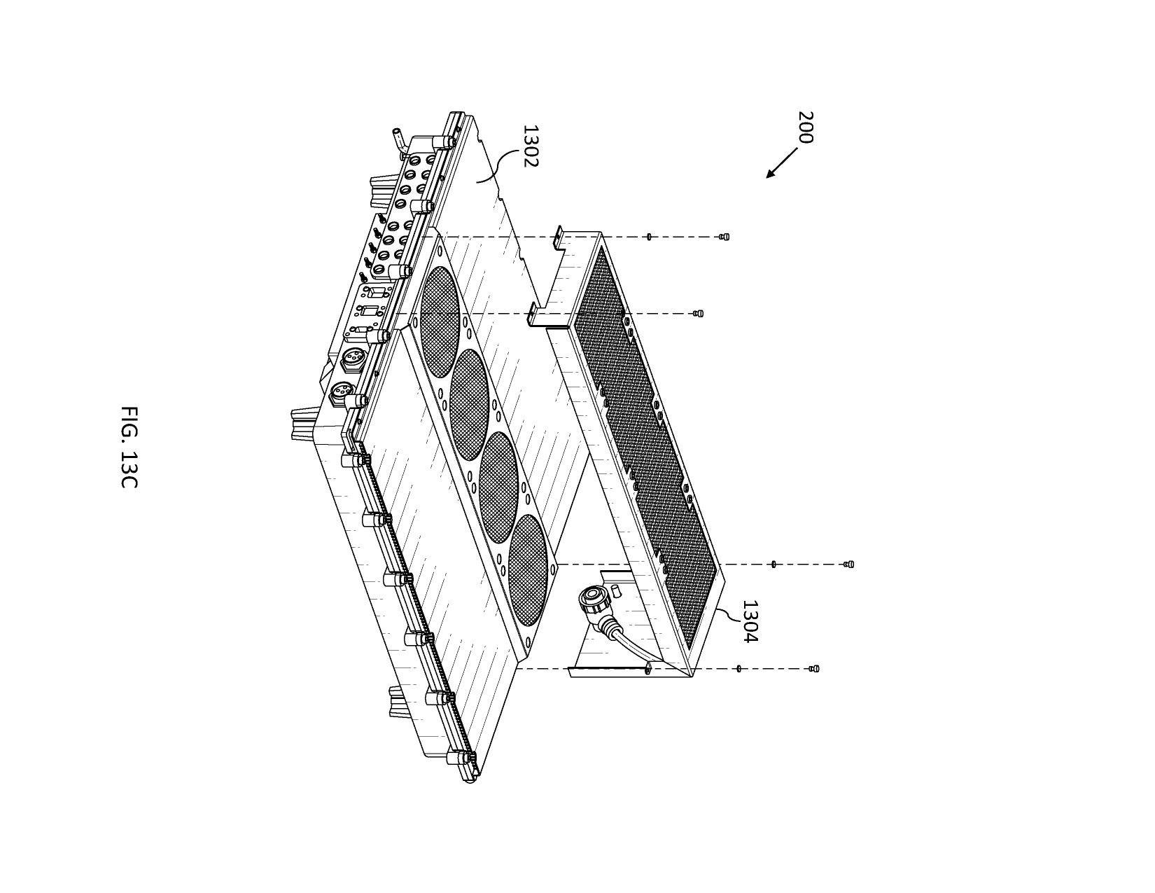

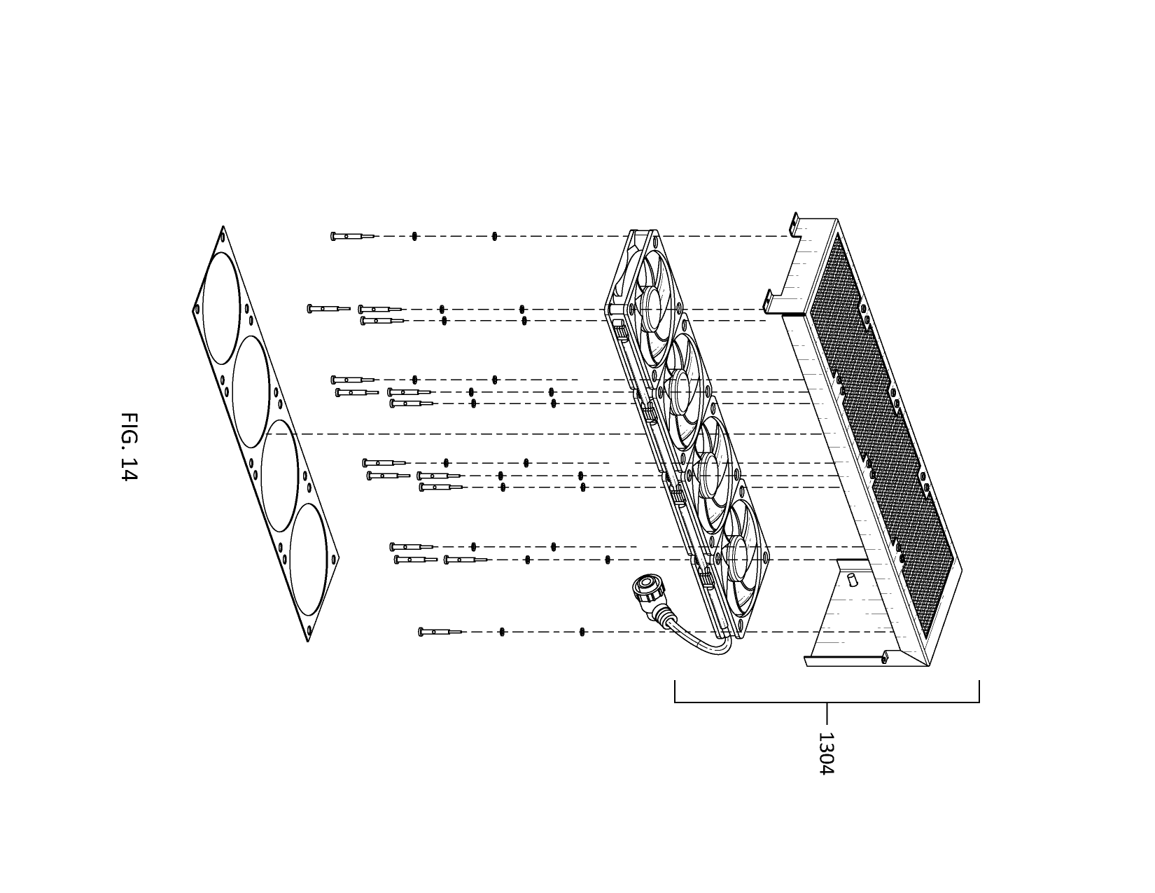

Moving to FIGS. 13A-14, the enclosure 200 may feature a front face cover 1302. Such a cover 1302 may be removeable to enable access to the interior of the enclosure 200. Such a removeable cover 1302 facilitates for ease of maintenance, allowing individuals to quickly remove and replace the cover 1302 to service the enclosure 200.

Additionally, the fans 306 may be incorporated into a single fan module 1304 able to be removed from the enclosure 200. To illustrate, one, two, three, four, or more individual fan units may be mechanically coupled within a common mounting framework or housing structure to form the fan module 1304. This integrated configuration enables coordinated operation of the one or more fans 306 with synchronized airflow patterns while maintaining the advantages of modular replacement. The fan module 1304 simplifies maintenance operations by eliminating the need to individually disconnect, remove, and reinstall separate fan components.

Moreover, the fan module 1304 may incorporate redundancy features where the loss of one or more individual fans within the module 1304 does not compromise overall cooling performance of the enclosure 200. This redundancy enhances system reliability and reduces the urgency of maintenance responses for fan failures.

Similarly, the fans 306 within the fan module 1304 may be independently operable. To illustrate, the controller may control the operation of each of the fans 306 within the module 1304. In an embodiment, the fans 306 within the module 1304 may be communicatively coupled to at least one of the internal temperature sensor, the external temperature sensor, and the controller. For instance, upon the outdoor ambient temperature and/or the dielectric coolant temperature exceeding a specific temperature threshold, the external temperature sensor and/or the internal temperature sensor may send a signal to the controller to turn on the fans 306 within the module 1304.

In another embodiment, the fans 306 may work in parallel or in series. In one example, when operating in parallel, the fans 306 may become operable simultaneously once outdoor ambient temperatures and/or internal dielectric coolant temperatures exceed a specific temperature threshold.

When operating in series, each of the fans 306 may become operable at various outdoor ambient temperatures and/or dielectric coolant temperatures, which provides redundancy and distributes power consumption over time, reducing electrical load spikes while maintaining consistent cooling performance. As a nonlimiting example, the fans 306 may comprise a first, second, third, and fourth fan, wherein the first fan becomes operable at a first temperature, the second fan becomes operable at a second temperature, the third fan becomes operable at a third temperature, and the fourth fan becomes operable at a fourth temperature. However, any number of fans may be incorporated in the fan module 1304.

In an embodiment, the one or more fans 306 may be removable. The removable one or more fans 306 may facilitate ease of servicing the cooling system, by enabling quick removal of the fans 306 from the system via one or more screws.

To facilitate transportation of the dielectric fluid, embodiments of the chassis 202 may include one or more fluid inputs and/or fluid outputs. Said inputs and/or outputs enable dielectric fluid to flow out of the chassis 202 through the fluid output, and back into the chassis 202 through the fluid input.

In some aspects, the enclosure 200 may include a coolant displacement block. In one or more embodiments, such a displacement block may be disposed within the interior space of the chassis 202. Further, the coolant displacement block may be configured as a hollow component to displace dielectric fluid within the chassis 202 and reduce an overall weight of the enclosure. The hollow configuration of the coolant displacement block may contain air or another gas, thereby displacing a volume of dielectric fluid that would otherwise occupy the same space within the interior space of the chassis 202.

In some cases, the coolant displacement block may be positioned within a spare power supply port of the chassis 202. The spare power supply port may provide a convenient location for the coolant displacement block where it does not interfere with electronic components or coolant flow paths within the interior space of the chassis 202.

In an embodiment, the coolant displacement block may be positioned in other available spaces within the chassis 202, such as between cables and electronic components. In such configurations, the coolant displacement block may have a more complex shape configured to conform to available space between cables and electronic components within the interior space of the chassis 202.

In some aspects, the coolant displacement block may be fabricated from 3D printed nylon. A 3D printed nylon coolant displacement block may include end caps secured to the coolant displacement block body to create a sealed hollow interior. In some cases, the end caps may be glued in place to maintain the sealed hollow configuration of the coolant displacement block. However, one of ordinary skill in the art will appreciate that the coolant displacement block may be fabricated from any suitable material including, but not limited to, blow molded plastic, injection molded polymers, foam materials with sealed outer skins, thin-walled metal containers, and the like. The material selection may be based on manufacturing considerations, weight requirements, and chemical compatibility with the dielectric fluid.

In some aspects, the enclosure 200 may include a plurality of coolant displacement blocks distributed throughout the interior space of the chassis 202 to maximize weight reduction. The plurality of coolant displacement blocks may be positioned in various available spaces within the chassis 202, including spare component ports, gaps between cables, and regions between electronic components on the IT board 204.

In some cases, the coolant displacement block may be configured in various shapes depending on available space within the chassis interior space. The coolant displacement block may comprise a cylindrical shape, a rectangular shape, a spherical shape, or an irregular shape configured to conform to available space between cables and electronic components. The shape of the coolant displacement block may be selected based on the geometry of the cavity in which the coolant displacement block is to be positioned.

In an embodiment, the coolant displacement block may be partially filled with a lightweight material such as foam or aerogel to provide structural support while maintaining weight reduction benefits. The lightweight fill material may prevent collapse of the coolant displacement block under hydrostatic pressure from the surrounding dielectric fluid while preserving the hollow configuration that displaces dielectric fluid.

In some aspects, the coolant displacement block may be configured as an inflatable bladder that can be inflated after installation within the chassis 202. The inflatable configuration may enable the coolant displacement block to conform to available space within the interior space of the chassis 202, maximizing dielectric fluid displacement in irregularly shaped cavities. The inflatable bladder may be inflated with air or an inert gas after positioning within the chassis 202.

In some cases, the coolant displacement block may include integrated features that serve dual purposes within the chassis 202. The coolant displacement block may include integrated mounting features for securing the coolant displacement block within the interior space of the chassis 202, cable routing channels for organizing cables within the chassis 202, or structural supports that provide mechanical reinforcement to adjacent components.

In some aspects, a plurality of smaller coolant displacement blocks may be configured as a modular system that can be combined or stacked to fill various cavity sizes within the chassis’ 202 interior space. The modular coolant displacement block system may enable customization of weight reduction based on available space and thermal management requirements for different deployment configurations.

The weight reduction provided by the coolant displacement block may be beneficial for telecommunications deployments where equipment mounted on poles or similar structures may be subject to weight requirements. In some aspects, the coolant displacement block may displace approximately 0.3 kilograms of dielectric fluid within the chassis 202. The weight reduction achieved through dielectric fluid displacement may enable the cooling enclosure apparatus to meet weight specifications for pole-mounted telecommunications or edge computing deployments.

In one or more embodiments, a cooling enclosure apparatus may be provided. The cooling enclosure apparatus may comprise an enclosure configured to be mounted to an outdoor structure. The cooling enclosure apparatus may comprise a chassis enclosed within the enclosure, the chassis including one or more heat fins. The cooling enclosure apparatus may comprise an IT board disposed within the chassis, the IT board having at least one electronic component disposed upon a surface thereof, wherein the chassis contains a sufficient amount of dielectric fluid to at least partially submerge the IT board. The cooling enclosure apparatus may comprise one or more radiators disposed adjacent to an exterior surface of the chassis, the one or more radiators being fluidly connected to a chassis interior space. The cooling enclosure apparatus may comprise one or more pumps configured to move dielectric fluid from the chassis interior space, through the one or more radiators, and back into the chassis interior space.

In some aspects, the one or more radiators and the chassis may define a coolant channel, wherein dielectric fluid circulates through the coolant channel to transfer heat to the one or more radiators.

In one or more embodiments, the cooling enclosure apparatus may further comprise a heater printed circuit board disposed within the chassis interior space and submerged in the dielectric fluid, wherein the heater printed circuit board comprises a plurality of resistors configured to generate heat to warm the dielectric fluid. The cooling enclosure apparatus may further comprise a controller communicatively coupled to the heater printed circuit board, wherein the controller is configured to selectively activate portions of the plurality of resistors based on a temperature of the dielectric fluid. In some aspects, the plurality of resistors may be configured to be activated in stages at different temperature thresholds to distribute power consumption over time.

In some aspects, the cooling enclosure apparatus may further comprise a coolant displacement block disposed within the chassis interior space, wherein the coolant displacement block is hollow and configured to displace dielectric fluid within the chassis to reduce an overall weight of the cooling enclosure apparatus. In some cases, the coolant displacement block may be positioned within a spare power supply port of the chassis.

In one or more embodiments, the cooling enclosure apparatus may further comprise one or more fans incorporated into a removable fan module.

In some aspects, the cooling enclosure apparatus may further comprise a heatsink thermally coupled to an electronic component disposed on the IT board, wherein the heatsink includes one or more slotted inlets configured to distribute dielectric coolant across a plurality of cooling fins extending from a base of the heatsink. The cooling enclosure apparatus may further comprise piping fluidly connecting a radiator outlet to the heatsink, wherein the piping is configured to deliver cooled dielectric fluid from the one or more radiators directly to the heatsink prior to the dielectric fluid entering the chassis interior space. In some cases, the cooling enclosure apparatus may further comprise a coolant distribution manifold fluidly connected to the heatsink via piping, wherein the coolant distribution manifold is configured to receive warmed dielectric coolant from the heatsink and distribute the warmed dielectric coolant to a bottom portion of the chassis interior space.

In one or more embodiments, a thermal management system for outdoor electronic equipment may be provided. The thermal management system may comprise a weatherproof enclosure configured for pole mounting. The thermal management system may comprise a thermally conductive chassis positioned within the weatherproof enclosure, the chassis defining an interior space containing a dielectric fluid. The thermal management system may comprise an IT board submerged in the dielectric fluid within the chassis interior space, the IT board supporting a plurality of electronic components. The thermal management system may comprise a heatsink thermally coupled to at least one of the plurality of electronic components. The thermal management system may comprise a radiator assembly fluidly connected to the chassis interior space, the radiator assembly and the thermally conductive chassis defining a coolant channel. The thermal management system may comprise a pump configured to circulate the dielectric fluid between the chassis interior space and the radiator assembly. The thermal management system may comprise a fan assembly positioned adjacent to the radiator assembly to direct airflow therethrough.

In some aspects, the heatsink may include one or more slotted inlets configured to distribute the dielectric fluid across a plurality of cooling fins extending from a base of the heatsink, and one or more slotted exit holes configured to facilitate controlled overflow of the dielectric fluid from the heatsink into the chassis interior space.

In one or more embodiments, the thermal management system may further comprise piping fluidly connecting a radiator outlet to the heatsink, wherein the piping is configured to deliver cooled dielectric fluid from the radiator assembly directly to the heatsink prior to the dielectric fluid entering the chassis interior space.

In some aspects, the thermal management system may further comprise a coolant displacement block disposed within the chassis interior space, wherein the coolant displacement block is hollow and positioned within a spare power supply port of the chassis to displace dielectric fluid and reduce an overall weight of the thermal management system.

In one or more embodiments, the thermal management system may further comprise a heater printed circuit board disposed within the chassis interior space and submerged in the dielectric fluid, wherein the heater printed circuit board comprises a bank of resistors configured to generate heat to warm the dielectric fluid, and a controller communicatively coupled to the heater printed circuit board and configured to selectively activate portions of the bank of resistors based on a temperature of the dielectric fluid.

In some aspects, the fan assembly may comprise a removable fan module incorporating a plurality of individual fan units mechanically coupled within a common mounting framework, wherein the removable fan module is configured to be removed from the weatherproof enclosure as a single unit for servicing.

In one or more embodiments, a method of thermally regulating electronic equipment in an outdoor environment may be provided. The method may comprise mounting an enclosure to an outdoor structure, the enclosure containing a chassis with an IT board disposed therein. The method may comprise submerging the IT board in dielectric fluid contained within the chassis. The method may comprise circulating the dielectric fluid from the chassis through one or more radiators using one or more pumps, wherein the one or more radiators and the chassis define a coolant channel therebetween. The method may comprise directing airflow through the one or more radiators using one or more fans to transfer heat from the dielectric fluid to an ambient environment.

In some aspects, the method may further comprise activating a heater printed circuit board disposed within a chassis interior space and submerged in the dielectric fluid to warm the dielectric fluid when an ambient temperature or a temperature of the dielectric fluid drops below a specific temperature threshold, wherein the heater printed circuit board comprises a plurality of resistors configured to generate heat.

In one or more embodiments, the method may further comprise routing cooled dielectric fluid from the one or more radiators directly to a heatsink thermally coupled to an electronic component generating a highest thermal output among electronic components on the IT board prior to the dielectric fluid entering a chassis interior space, wherein the electronic component may comprise a processor, a graphics processing unit, or similar high-power component.

Finally, other implementations of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

Various elements, which are described herein in the context of one or more embodiments, may be provided separately or in any suitable subcombination. Further, the processes described herein are not limited to the specific embodiments described. For example, the processes described herein are not limited to the specific processing order described herein and, rather, process blocks may be re-ordered, combined, removed, or performed in parallel or in serial, as necessary, to achieve the results set forth herein.

It will be further understood that various changes in the details, materials, and arrangements of the parts that have been described and illustrated herein may be made by those skilled in the art without departing from the scope of the following claims.

All references, patents and patent applications and publications that are cited or referred to in this application are incorporated in their entirety herein by reference. Finally, other implementations of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

What is claimed is:

1. A cooling enclosure apparatus, comprising:
an enclosure configured to be mounted to an outdoor structure;
a chassis enclosed within an enclosure, the chassis including one or more heat fins;
an IT board disposed within the chassis, the IT board having at least one electronic component disposed upon a surface thereof, wherein the chassis contains a sufficient amount of dielectric fluid to at least partially submerge the IT board;
one or more radiators disposed adjacent to an exterior surface of the chassis, the one or more radiators being fluidly connected to a chassis interior space; and
one or more pumps configured to move dielectric fluid from the chassis interior space, through the one or more radiators, and back into the chassis interior space.

2. The cooling enclosure apparatus of claim 1, wherein the one or more radiators and the chassis define a coolant channel, wherein dielectric fluid circulates through the coolant channel to transfer heat to the one or more radiators.

3. The cooling enclosure apparatus of claim 1, further comprising a heater printed circuit board disposed within the chassis interior space and submerged in the dielectric fluid, wherein the heater printed circuit board comprises a plurality of resistors configured to generate heat to warm the dielectric fluid.

4. The cooling enclosure apparatus of claim 3, further comprising a controller communicatively coupled to the heater printed circuit board, wherein the controller is configured to selectively activate portions of the plurality of resistors based on a temperature of the dielectric fluid.

5. The cooling enclosure apparatus of claim 4, wherein the plurality of resistors are configured to be activated in stages at different temperature thresholds to distribute power consumption over time.

6. The cooling enclosure apparatus of claim 1, further comprising a coolant displacement block disposed within the chassis interior space, wherein the coolant displacement block is hollow and configured to displace dielectric fluid within the chassis to reduce an overall weight of the cooling enclosure apparatus.

7. The cooling enclosure apparatus of claim 6, wherein the coolant displacement block is positioned within a spare power supply port of the chassis.

8. The cooling enclosure apparatus of claim 1, further comprising one or more fans incorporated into a removable fan module.

9. The cooling enclosure apparatus of claim 1, further comprising a heatsink thermally coupled to an electronic component disposed on the IT board, wherein the heatsink includes one or more slotted inlets configured to distribute dielectric coolant across a plurality of cooling fins extending from a base of the heatsink.

10. The cooling enclosure apparatus of claim 9, further comprising piping fluidly connecting a radiator outlet to the heatsink, wherein the piping is configured to deliver cooled dielectric fluid from the one or more radiators directly to the heatsink prior to the dielectric fluid entering the chassis interior space.

11. The cooling enclosure apparatus of claim 9, further comprising a coolant distribution manifold fluidly connected to the heatsink via piping, wherein the coolant distribution manifold is configured to receive warmed dielectric coolant from the heatsink and distribute the warmed dielectric coolant to a bottom portion of the chassis interior space.

12. A thermal management system for outdoor electronic equipment, comprising:
a weatherproof enclosure configured for pole mounting;
a thermally conductive chassis positioned within the weatherproof enclosure, the chassis defining an interior space containing a dielectric fluid;
an IT board submerged in the dielectric fluid within the chassis interior space, the IT board supporting a plurality of electronic components;
a heatsink thermally coupled to at least one of the plurality of electronic components;
a radiator assembly fluidly connected to the chassis interior space, the radiator assembly and the thermally conductive chassis defining a coolant channel;
a pump configured to circulate the dielectric fluid between the chassis interior space and the radiator assembly; and
a fan assembly positioned adjacent to the radiator assembly to direct airflow therethrough.

13. The thermal management system of claim 12, wherein the heatsink includes one or more slotted inlets configured to distribute the dielectric fluid across a plurality of cooling fins extending from a base of the heatsink, and one or more slotted exit holes configured to facilitate controlled overflow of the dielectric fluid from the heatsink into the chassis interior space.

14. The thermal management system of claim 13, further comprising piping fluidly connecting a radiator outlet to the heatsink, wherein the piping is configured to deliver cooled dielectric fluid from the radiator assembly directly to the heatsink prior to the dielectric fluid entering the chassis interior space.

15. The thermal management system of claim 12, further comprising a coolant displacement block disposed within the chassis interior space, wherein the coolant displacement block is hollow and positioned within a spare power supply port of the chassis to displace dielectric fluid and reduce an overall weight of the thermal management system.

16. The thermal management system of claim 12, further comprising a heater printed circuit board disposed within the chassis interior space and submerged in the dielectric fluid, wherein the heater printed circuit board comprises a bank of resistors configured to generate heat to warm the dielectric fluid, and a controller communicatively coupled to the heater printed circuit board and configured to selectively activate portions of the bank of resistors based on a temperature of the dielectric fluid.

17. The thermal management system of claim 12, wherein the fan assembly comprises a removable fan module incorporating a plurality of individual fan units mechanically coupled within a common mounting framework, wherein the removable fan module is configured to be removed from the weatherproof enclosure as a single unit for servicing.

18. A method of thermally regulating electronic equipment in an outdoor environment, comprising:
mounting an enclosure to an outdoor structure, the enclosure containing a chassis with an IT board disposed therein;
submerging the IT board in dielectric fluid contained within the chassis;
circulating the dielectric fluid from the chassis through one or more radiators using one or more pumps, wherein the one or more radiators and the chassis define a coolant channel therebetween; and
directing airflow through the one or more radiators using one or more fans to transfer heat from the dielectric fluid to an ambient environment.

19. The method of claim 18, further comprising activating a heater printed circuit board disposed within a chassis interior space and submerged in the dielectric fluid to warm the dielectric fluid when an ambient temperature or a temperature of the dielectric fluid drops below a specific temperature threshold, wherein the heater printed circuit board comprises a plurality of resistors configured to generate heat.

20. The method of claim 18, further comprising routing cooled dielectric fluid from the one or more radiators directly to a heatsink thermally coupled to an electronic component generating a highest thermal output among electronic components on the IT board prior to the dielectric fluid entering a chassis interior space, wherein the electronic component may comprise a processor, a graphics processing unit, or similar high-power component.
